(19) United States
(12) Patent Application Publication
(10) Pub. No.: US 2026/0164584 A1
(43) Pub. Date: Jun. 11, 2026

(54) CIRCUIT BOARD COUPLING STRUCTURE

(71) Applicant: HIROSE ELECTRIC CO., LTD., Kanagawa (JP)

(72) Inventor: Yuya YOSHIHARA, Kanagawa (JP)

(21) Appl. No.: 19/407,779

(22) Filed: Dec. 3, 2025

(30) Foreign Application Priority Data
Dec. 9, 2024 (JP) 2024-214313

(51) Int. Cl. H05K 7/14

(52) U.S. Cl. CPC H05K 7/1424

(57) ABSTRACT

Provided is a circuit board coupling structure, circuit boards being disposed such that a first and second principal surfaces are perpendicular to a coupling direction, each of a first connector on the first principal surface and a second connector on the second principal surface having terminals and a housing, the first connector and the second connector being fitted in and connected to each other with one direction parallel with the first and second principal surfaces as an insertion-removal direction, the circuit boards being electrically connected in such a manner that the first and second connectors are fitted in and connected to each other, a first guide locking portion of the housing of the first connector and a second guide locking portion of the housing of the second connector being configured to guide each other in the insertion-removal direction and be locked to each other in the coupling direction.

### CROSS-REFERENCE TO RELATED APPLICATION

This application claims priority from Japanese Patent Application No. 2024-214313 filed with the Japan Patent Office on December 9, 2024, the entire content of which is hereby incorporated by reference.

### BACKGROUND

### 1. Technical Field

The present disclosure relates to a circuit board coupling structure.

### 2. Related Art

JP-A-2005-019861 discloses a structure for connecting a plurality of circuit boards provided with male connectors in one case. An opening for receiving the circuit boards is formed in one side portion of the case, and one main board is disposed at the other side portion located opposite to the opening. Each circuit board is inserted from the opening to the main board in a posture perpendicular to the main board with a direction parallel with the plate surface of the circuit board as an insertion direction. The male connector of the circuit board is fitted in and connected to a female connector provided for the main board in the insertion direction. As a result, the plurality of circuit boards is arranged in a direction perpendicular to the plate surface, and are indirectly connected to each other via the main board.

### SUMMARY

A circuit board coupling structure according to the present disclosure is a circuit board coupling structure for coupling a plurality of circuit boards, each of the plurality of circuit boards having a first principal surface and a second principal surface opposite to the first principal surface, and the plurality of circuit boards being disposed such that the first and second principal surfaces are perpendicular to a coupling direction of the plurality of circuit boards, a first connector being mounted on the first principal surface, a second connector being mounted on the second principal surface, and each of the first connector and the second connector having a plurality of terminals and a housing holding the plurality of terminals, the first connector and the second connector being fitted in and connected to each other with one direction parallel with the first and second principal surfaces as an insertion-removal direction, adjacent ones of the circuit boards being electrically connected in such a manner that the first and second connectors facing each other in the coupling direction are fitted in and connected to each other, the housing of the first connector having a first guide locking portion, and the housing of the second connector having a second guide locking portion, and the first and second guide locking portions being configured to guide each other in the insertion-removal direction in a course of fitting and connecting the first and second connectors and be locked to each other in the coupling direction in a state of the first and second connectors being fitted in and connected to each other.

### BRIEF DESCRIPTION OF THE DRAWINGS

FIGS. 1A and 1B are perspective views of an electronic device in an embodiment of the present disclosure, FIG. 1A showing a state immediately before one connector mounting body is attached and FIG. 1B showing a state of all the connector mounting bodies being attached;

FIG. 2 is a side view of the electronic device from the rear;

FIGS. 3A and 3B are perspective views of the connector mounting body alone, FIG. 3A showing a state from one mounting surface side and FIG. 3B showing a state from the other mounting surface side;

FIG. 4 is a perspective view of a plug connector;

FIG. 5 is an exploded perspective view of each member forming the plug connector;

FIG. 6A is a perspective view of a plug signal terminal alone, and FIG. 6B is a perspective view of a plug power terminal alone;

FIG. 7A is a plan view of part of the plug connector when viewed in a coupling direction, and FIG. 7B is a sectional view of part of the plug connector taken along a plane perpendicular to an insertion-removal direction;

FIG. 8A is a sectional view taken along VIIIA-VIIIA line of FIG. 7A, and FIG. 8B is a sectional view taken along VIIIB-VIIIB line of FIG. 7A;

FIG. 9 is a perspective view of a socket connector;

FIG. 10 is an exploded perspective view of each member forming the socket connector;

FIG. 11A is a perspective view of a socket signal terminal alone, and FIG. 11B is a perspective view of a socket power terminal alone;

FIG. 12A is a plan view of part of the socket connector when viewed in the coupling direction, and FIG. 12B is a side view of part of the socket connector when viewed in the coupling direction;

FIG. 13A is a sectional view taken along XIIIA-XIIIA line of FIG. 12A, and FIG. 13B is a partially-enlarged view of FIG. 13A;

FIG. 14 is a sectional view taken along XIV-XIV line of FIG. 12A;

FIGS. 15A and 15B are perspective views of a connector assembly including the plug connector and the socket connector, FIG. 15A showing a state before fitting connection and FIG. 15B showing a fitting connection state;

FIG. 16 is a sectional view of the connector assembly taken along a plane perpendicular to a terminal arrange direction, and shows a section at the position of the signal terminal,

FIG. 17 is a sectional view of the connector assembly taken along the plane perpendicular to the terminal arrangement direction, and shows a section at the position of the power terminal, and

FIG. 18 is a side view of the connector assembly in the fitting connection state when viewed in the insertion-removal direction.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In JP-A-2005-019861, the plurality of circuit boards is connected via the main board. On the main board, the same number of female connectors to be connected to the male connectors of the circuit boards as the number of male connectors is mounted. For this reason, in JP-A-2005-019861, the main board and many female connectors are required, and therefore, there is still room for improvement in reduction in the number of components.

The present disclosure has been made in view of such a situation, and one object thereof is to provide a coupling structure capable of coupling a plurality of circuit boards while suppressing an increase in the number of components.

(1) A circuit board coupling structure according to the present disclosure is a circuit board coupling structure for coupling a plurality of circuit boards, each of the plurality of circuit boards having a first principal surface and a second principal surface opposite to the first principal surface, and the plurality of circuit boards being disposed such that the first and second principal surfaces are perpendicular to a coupling direction of the plurality of circuit boards, a first connector being mounted on the first principal surface, a second connector being mounted on the second principal surface, and each of the first connector and the second connector having a plurality of terminals and a housing holding the plurality of terminals, the first connector and the second connector being fitted in and connected to each other with one direction parallel with the first and second principal surfaces as an insertion-removal direction, adjacent ones of the circuit boards being electrically connected in such a manner that the first and second connectors facing each other in the coupling direction are fitted in and connected to each other, the housing of the first connector having a first guide locking portion, and the housing of the second connector having a second guide locking portion, and the first and second guide locking portions being configured to guide each other in the insertion-removal direction in a course of fitting and connecting the first and second connectors and be locked to each other in the coupling direction in a state of the first and second connectors being fitted in and connected to each other.

In the disclosure of (1) above, in arbitrary two adjacent circuit boards, the connectors provided on the opposing mounting surfaces (principal surfaces), that is, the first and second connectors, are fitted in and connected to each other in the insertion-removal direction parallel with the mounting surface of the circuit board. In the disclosure of (1) above, the adjacent circuit boards are connected via the connectors (first connector provided on the first principal surface of the circuit board and second connector provided on the second principal surface of the circuit board) provided on the mounting surfaces of the circuit boards. Thus, a main board for connecting a plurality of circuit boards and a connector mounted on the main board as in the related art are not necessary, and an increase in the number of components can be suppressed. Moreover, in the disclosure of (1) above, the first guide locking portion of the first connector and the second guide locking portion of the second connector guide each other in the insertion-removal direction in the course of the connector fitting connection of the first and second connectors, and therefore, the connectors can be smoothly fitted in and connected to each other. The first and second connectors are locked to each other in the coupling direction in the connector fitting connection state, and therefore, a stable connector fitting connection state can be favorably maintained.

(2) In the disclosure of (1), it may be configured such that one of the first guide locking portion or the second guide locking portion has a projection, the other one has a groove, the projection protrudes in a direction perpendicular to the coupling direction and the insertion-removal direction and extends in the insertion-removal direction, and the groove extends in the insertion-removal direction, and in the course of fitting and connecting the first and second connectors, receives and guides the projection.

(3) A circuit board coupling structure according to the present disclosure is a circuit board coupling structure for coupling a plurality of circuit boards, each of the plurality of circuit boards having a first principal surface and a second principal surface opposite to the first principal surface, and the plurality of circuit boards being disposed such that the first and second principal surfaces are perpendicular to a coupling direction of the plurality of circuit boards, a first connector being mounted on the first principal surface, a second connector being mounted on the second principal surface, and each of the first and second connectors having a plurality of terminals and a housing holding the plurality of terminals, the first and second connectors being fitted in and connected to each other with one direction parallel with the first and second principal surfaces as an insertion-removal direction, adjacent ones of the circuit boards being electrically connected in such a manner that the first and second connectors facing each other in the coupling direction are fitted in and connected to each other, and at least any one of the housing of the first connector or the housing of the second connector is displaceable in a direction perpendicular to the insertion-removal direction.

In the disclosure of (3) above, in arbitrary two adjacent circuit boards, the connectors provided on the opposing mounting surfaces (principal surfaces), that is, the first and second connectors, are fitted in and connected to in the insertion-removal direction parallel with the mounting surface of the circuit board. In the disclosure of (3), the adjacent circuit boards are connected via the connectors (first connector provided on the first principal surface of the circuit board and second connector provided on the second principal surface) provided on the mounting surfaces of the circuit boards. Thus, a main board for connecting a plurality of circuit boards and a connector mounted on the main board as in the related art are not necessary, and an increase in the number of components can be suppressed. Moreover, in the disclosure of (3), even in a case where the relative positions of the first and second connectors are shifted from normal positions in the direction perpendicular to the insertion-removal direction, the shift of the connectors can be absorbed by displacement of the housing of at least one of the first connector or the second connector in the course of the connector fitting connection and in the connector fitting connection state.

(4) In the disclosure of (3), it may be configured such that at least any one of the housing of the first connector or the housing of the second connector has a fixed housing fixed to the circuit boards via the plurality of terminals, and a movable housing movable relative to the fixed housing, and the plurality of terminals is bridged between the fixed housing and the movable housing, and is configured to allow movement of the movable housing relative to the fixed housing by elastic displacement of the plurality of terminals.

In the present disclosure, the coupling structure capable of coupling the plurality of circuit boards while suppressing an increase in the number of components can be provided.

Hereinafter, an embodiment of the present disclosure will be described based on the attached drawings.

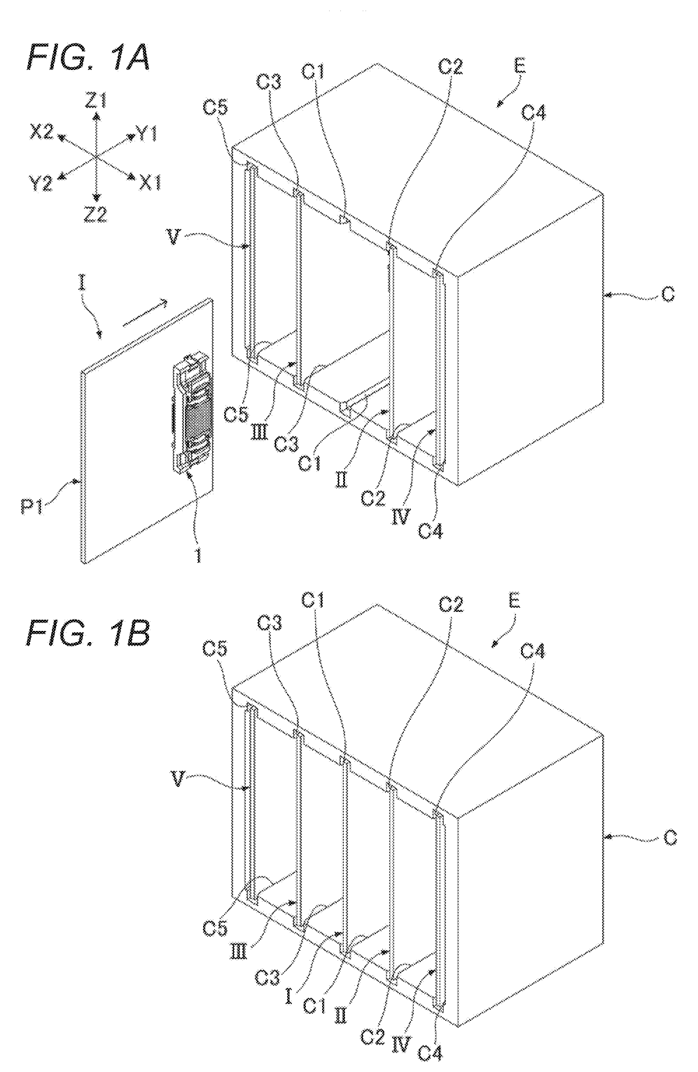

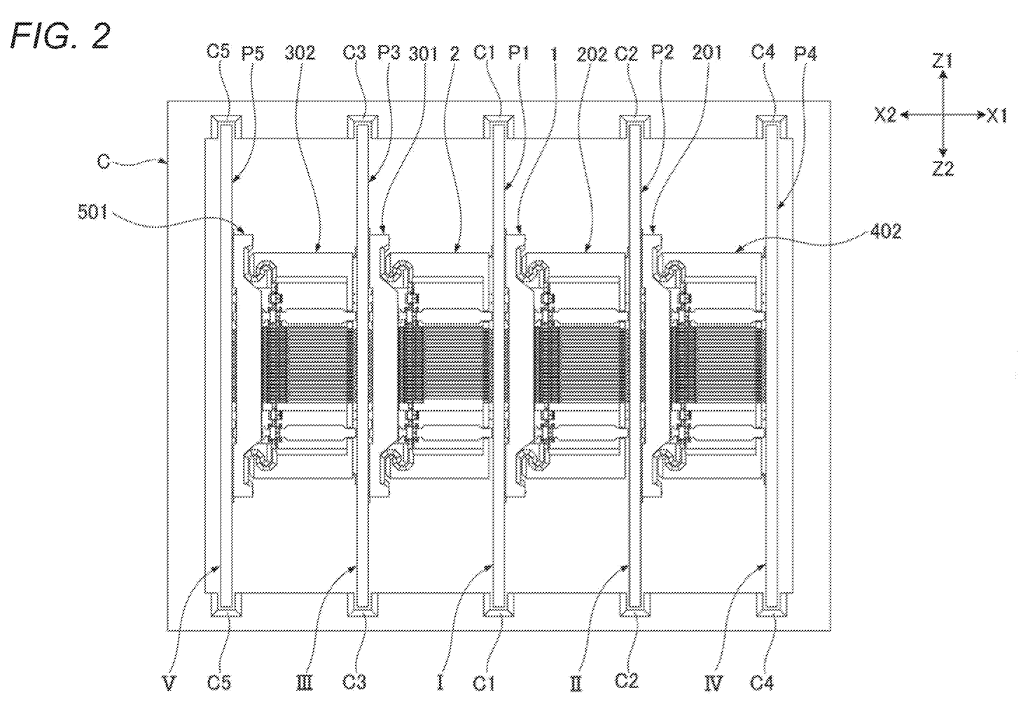

FIGS. 1A and 1B are perspective views of an electronic device in the embodiment of the present disclosure. FIG. 1A shows a state immediately before one connector mounting body is attached, and FIG. 1B shows a state of all the connector mounting bodies being attached. FIG. 2 is a side view of the electronic device from the rear. The electronic device E of the present embodiment has a case C with a substantially rectangular parallelepiped outer shape, and a plurality of (five in the present embodiment) connector mounting bodies I to V coupled in the case C with an X-axis direction as a coupling direction. The electronic device E is used for, for example, a control system provided in a semiconductor manufacturing device.

Hereinafter, a direction of coupling a plurality of circuit boards will be described as the X-axis direction, an insertion-removal direction (front-rear direction) when connectors are fitted in and connected to each other will be described as a Y-axis direction, and a terminal arrangement direction of arranging terminals of the connectors will be described as a Z-axis direction. The X-axis direction is a direction perpendicular to a mounting surface of the circuit board, and is a direction of locking the connectors to each other. The Y-axis direction is the front-rear direction, and a Y1 direction and a Y1 side are a forward direction and a front side and a Y2 direction and a Y2 side are a rearward direction and a rear side.

In the present embodiment, the connector mounting body IV, the connector mounting body II, the connector mounting body I, the connector mounting body III, and the connector mounting body V are disposed and coupled in this order from an X1 side. As shown in FIGS. 1A and 1B, the connector mounting bodies I to V are attached so as to be insertable into and removable from the case C with the front-rear direction (Y-axis direction) as the insertion-removal direction. Specifically, the connector mounting bodies I to V are inserted forward (Y1 direction) and attached to the case C, and is removed rearward (Y2 direction) and detached from the case C.

The case C is formed with rails C1 to C5 at equal intervals in the X-axis direction. The rails C1 to C5 are formed as grooves recessed from the upper and lower inner surfaces of the case C and extending in the front-rear direction at positions corresponding to the connector mounting bodies I to V. Upon attachment to and detachment from the case C, upper and lower end portions of circuit boards P1 to P5 (described later) of the connector mounting bodies I to V are guided in the front-rear direction by the rails C1 to C5. Movement of the upper and lower end portions of the circuit boards P1 to P5 in the coupling direction (X-axis direction) is restricted by the groove inner surfaces of the rails C1 to C5, and therefore, the connector mounting bodies I to V are positioned in the coupling direction. Each of the rails C1 to C5 has a front end surface closing the front end thereof. The connector mounting bodies I to V attached to the case C are positioned in the front-rear direction in such a manner that the circuit boards P1 to P5 contact the front end surfaces of the rails C1 to C5 from the rear.

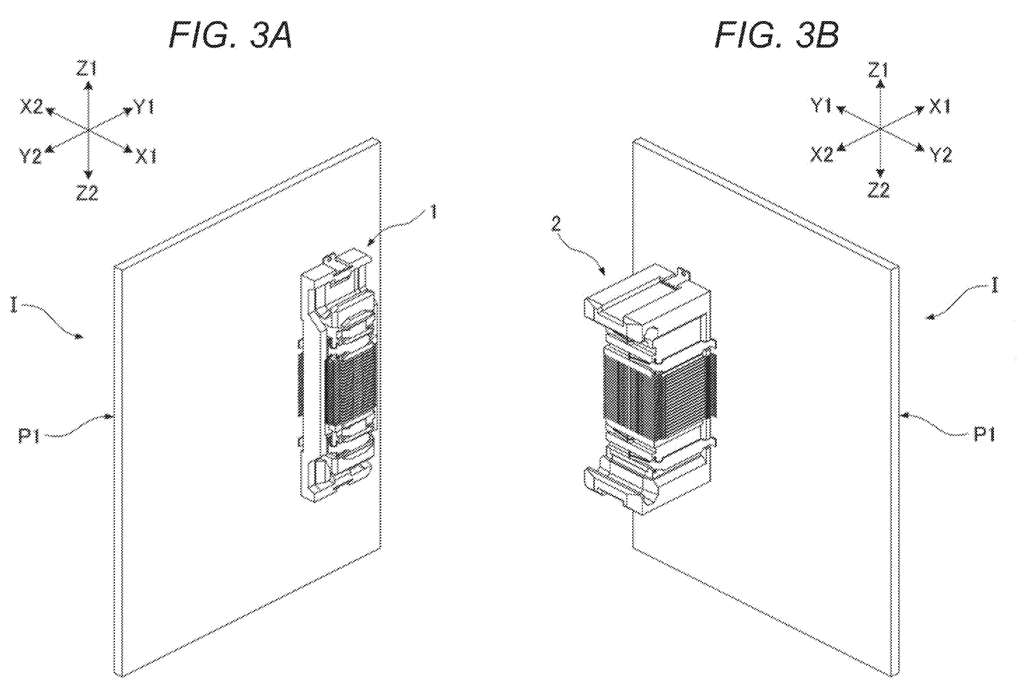

The connector mounting body I has the circuit board P1 disposed such that the plate surface thereof is perpendicular to the coupling direction (X-axis direction), a plug connector 1 as a first connector, and a socket connector 2 as a second connector. The circuit board P1 has mounting surfaces at both plate surfaces (principal surfaces), that is, both the X1-side plate surface and the X2-side plate surface. As shown in FIGS. 2, 3A, and 3B, the plug connector 1 is a circuit board electric connector mounted on the front end side (Y1 side) of the X1-side mounting surface, and the socket connector 2 is a circuit board electric connector mounted on the front end side (Y1 side) of the X2-side mounting surface.

The connector mounting bodies II, III have exactly the same configurations as that of the connector mounting body I. Specifically, as shown in FIG. 2, the connector mounting body II has the circuit board P2, a plug connector 201 as a first connector, and a socket connector 202 as a second connector. The connector mounting body III has the circuit board P3, a plug connector 301 as a first connector, and a socket connector 302 as a second connector.

The connector mounting bodies IV, V are different from the connector mounting bodies I to III in that the connector is mounted only on one surface of the circuit board. Specifically, the connector mounting body IV has the circuit board P4 and a socket connector 402 as a second connector. Since the connector mounting body IV is disposed closest to the X1 side, the circuit board P4 has a mounting surface only at the X2-side plate surface, and the socket connector 402 is disposed on such a mounting surface. The connector mounting body V has the circuit board P5 and a plug connector 501 as a first connector. Since the connector mounting body V is disposed closest to the X2 side, the circuit board P5 has a mounting surface only at the X1-side plate surface, and the plug connector 501 is disposed on such a mounting surface.

In arbitrary two adjacent connector mounting bodies of the connector mounting bodies I to V, the connectors disposed on the opposing mounting surfaces of the circuit boards are fitted in and connected to each other with the front-rear direction (Y-axis direction) as a fitting connection direction. For example, in the connector mounting body I, the plug connector 1 is fitted in and connected to the socket connector 202 of the connector mounting body II, and the socket connector 2 is fitted in and connected to the plug connector 301 of the connector mounting body III. The plug connector 1 and the socket connector 202 are insertable into and removable from each other with the Y-axis direction as the insertion-removal direction. Similarly, the socket connector 2 and the plug connector 301 are insertable into and removable from each other with the Y-axis direction as the insertion-removal direction. In this case, the socket connector 202 is a mating connector for the plug connector 1, and the plug connector 1 is a mating connector for the socket connector 202. Moreover, the plug connector 301 is a mating connector for the socket connector 2, and the socket connector 2 is a mating connector for the plug connector 301.

The connectors are fitted in and connected to each other with the front-rear direction (Y-axis direction) parallel with the mounting surfaces of the circuit boards P1 to P5 as the insertion-removal direction, and in this manner, the plurality of circuit boards P1 to P5 is coupled with the X-axis direction as the coupling direction. In the following description, such fitting and connection of the connectors may be referred to as connector fitting connection.

Hereinafter, the configurations of the plug connector 1 and socket connector 2 of the connector mounting body I will be described. The configurations of the plug connectors 201, 301, 501 are the same as the configuration of the plug connector 1, and therefore, the description thereof will be omitted. Moreover, the configurations of the socket connectors 202, 302, 402 are the same as the configuration of the socket connector 2, and therefore, the description thereof will be omitted.

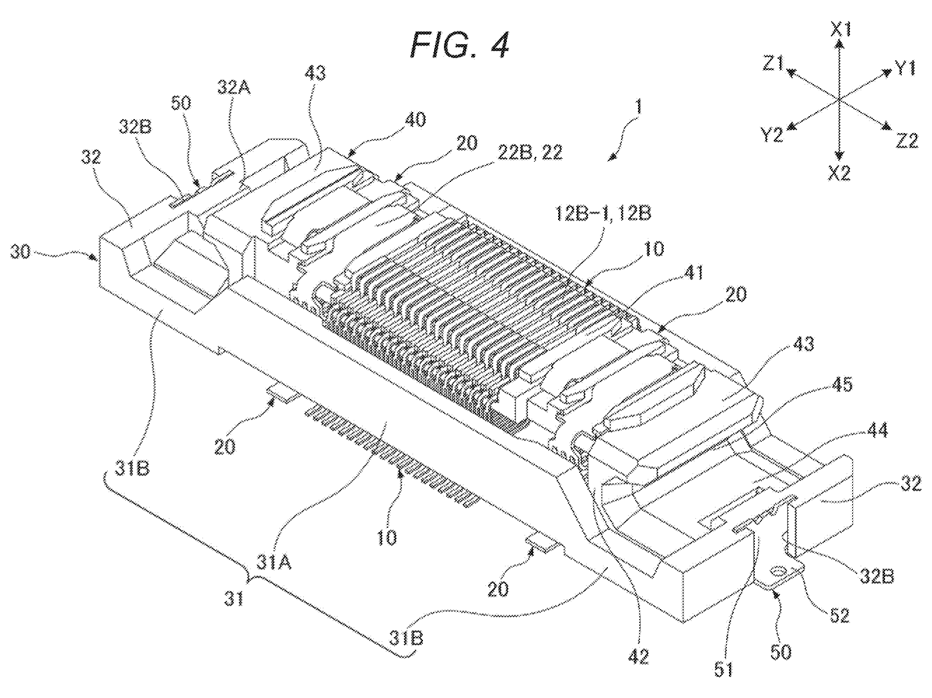

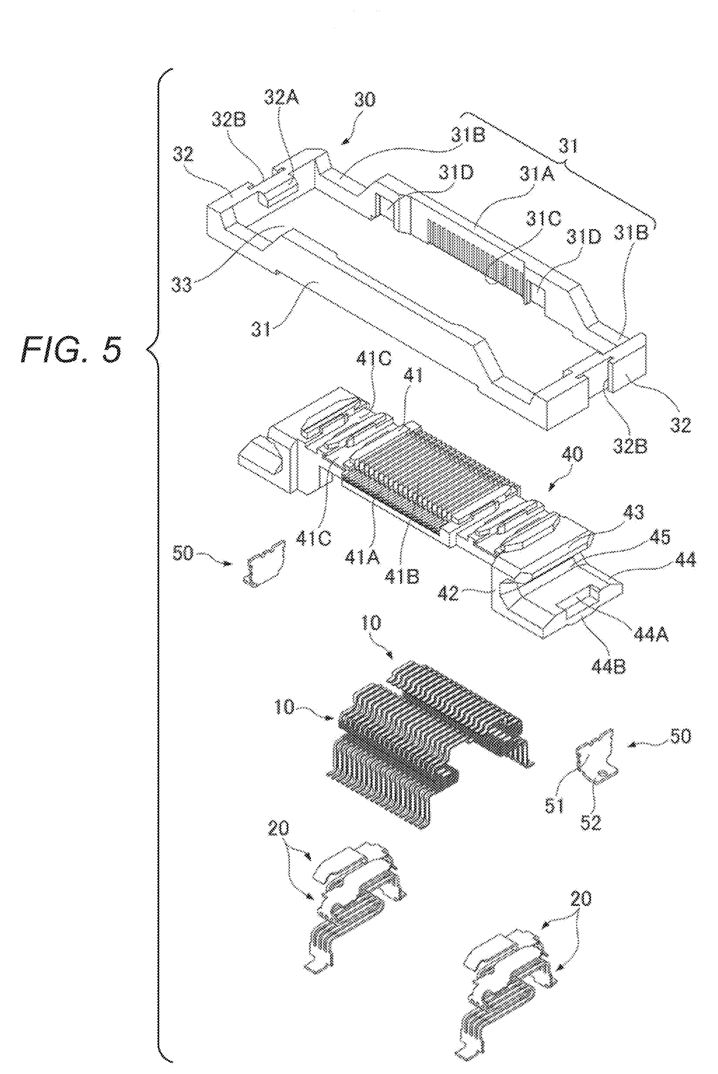

As shown in FIGS. 4 and 5, the plug connector 1 has a plurality of plug signal terminals 10, a plurality of plug power terminals 20, a plurality of plug metal fixtures 50, and a plug housing. The plurality of plug signal terminals 10, the plurality of plug power terminals 20, and the plurality of plug metal fixtures 50 are held by the plug housing. The plug housing has a fixed housing 30 fixed to the circuit board P1 via the plurality of plug signal terminals 10 and the plurality of plug power terminals 20, and a movable housing 40 movable relative to the fixed housing 30. In the following description, the plug signal terminal 10 and the plug power terminal 20 may be referred to as a plug terminal(s) 10, 20.

As shown in FIGS. 4 and 5, the plurality of plug terminals 10, 20 is arranged with a direction (Z-axis direction) perpendicular to both the coupling direction (X-axis direction) and the front-rear direction (Y-axis direction) as the terminal arrangement direction. The plug terminal 10, 20 is formed in such a manner that a metal band-shaped piece is bent in the plate thickness direction thereof. The plug terminal 10, 20 is disposed in such a posture that the plate surface thereof is perpendicular to the terminal arrangement direction, and is bridged between the fixed housing 30 and the movable housing 40.

The plug terminals 10, 20 are arranged so as to form two terminal lines, specifically a rear terminal line and a front terminal line. Here, the “rear terminal line” is formed of the plug terminals 10, 20 attached to the movable housing 40 from the rear (Y2 side). The “front terminal line” is formed of the plug terminals 10, 20 attached to the movable housing 40 from the front (Y1 side).

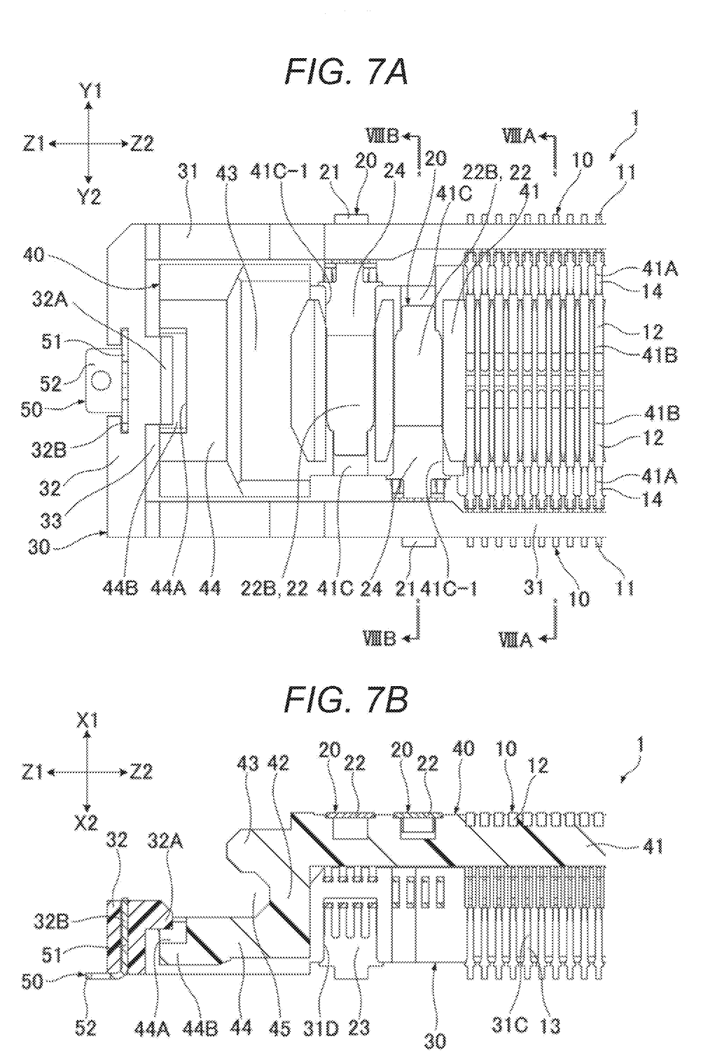

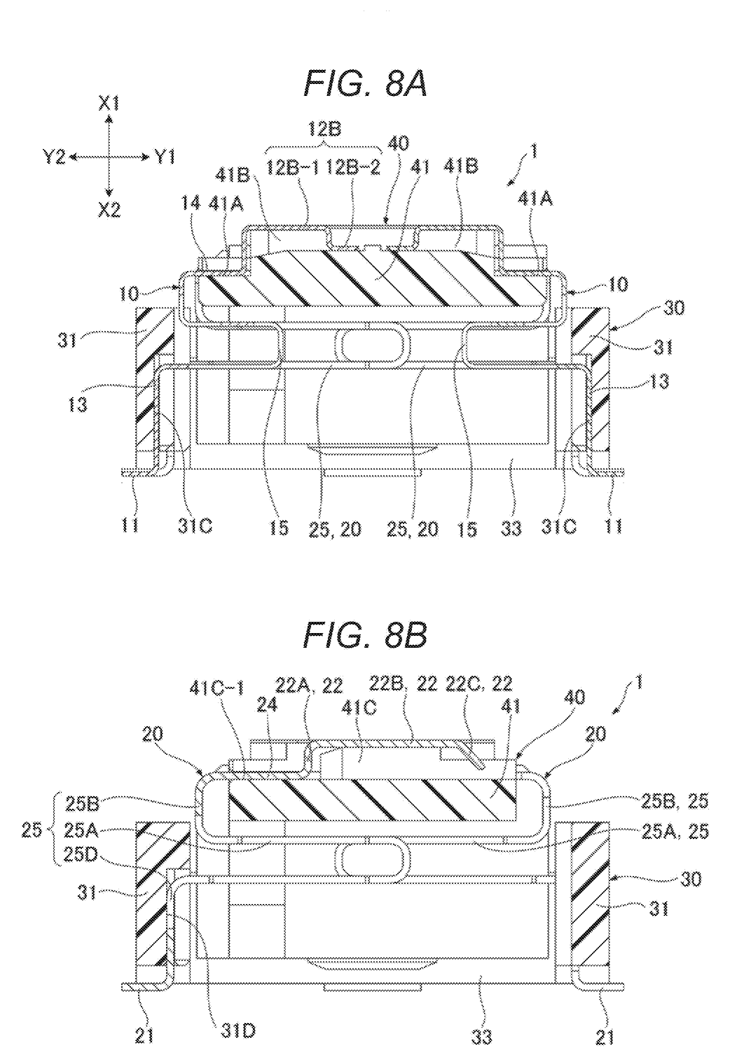

As shown in FIG. 5, the plug signal terminals 10 of the two terminal lines are disposed in postures symmetrical in the front-rear direction at the same positions in the terminal arrangement direction (also see FIGS. 7A and 8A). The plug signal terminals 10 are disposed in the two terminal lines as described above, and therefore, an increase in the size of the plug connector 1 in the terminal arrangement direction can be suppressed to the minimum while the number of plug signal terminals 10 is increased.

As shown in FIGS. 4 and 5, two plug power terminals 20 are disposed on each side of the area where the plug signal terminals 10 are arranged in the terminal arrangement direction. Here, on each side, the plug power terminals 20 attached to the movable housing 40 from the rear are included in the rear terminal line, and the plug power terminals 20 attached to the movable housing 40 from the front are included in the front terminal line. Moreover, on each side, the two plug power terminals 20 are disposed in postures symmetrical in the front-rear direction at different positions in the terminal arrangement direction.

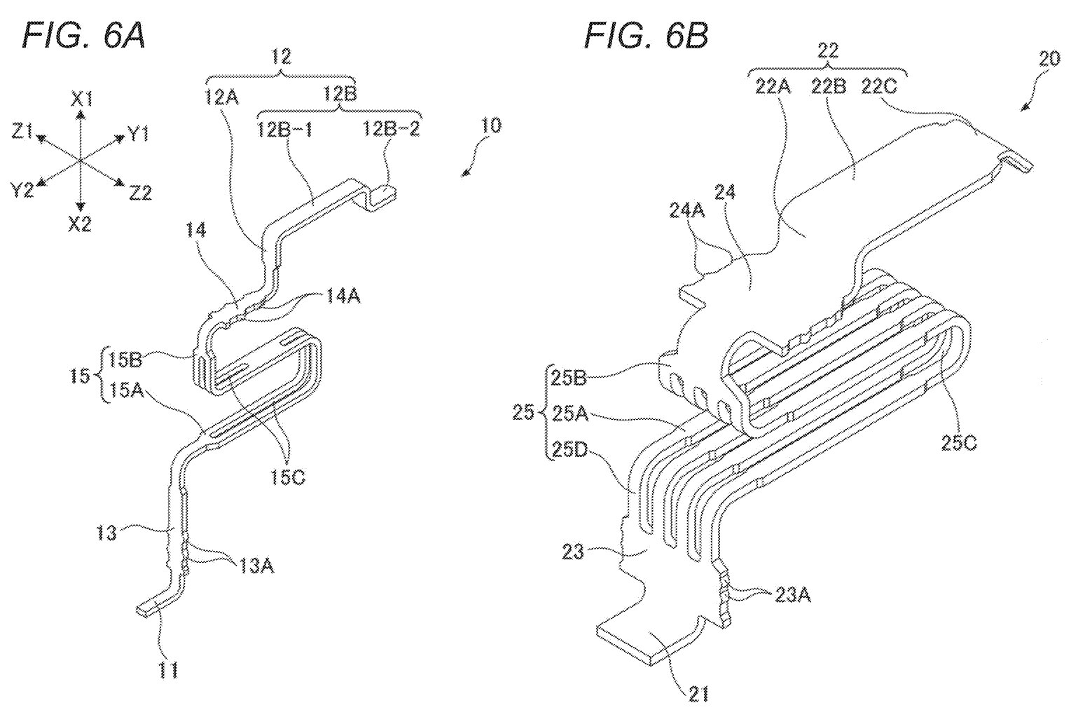

FIG. 6A is a perspective view of the plug signal terminal 10 alone. FIG. 6A shows the plug signal terminal 10 of the rear (Y2-side) terminal line. Here, the configuration of the plug signal terminal 10 of the rear (Y2-side) terminal line will be described based on FIG. 6A. The plug signal terminal 10 of the front (Y1-side) terminal line has the same shape as that of the plug signal terminal 10 shown in FIG. 6A, and therefore, the description thereof will be omitted.

The plug signal terminal 10 has a signal connection portion 11 provided on one end side of the plug signal terminal 10 and to be connected to the circuit board P1, a signal contact arm portion 12 provided on the other end side of the plug signal terminal 10 and configured to contact the socket connector 202 as the mating connector, a fixed-side holding target portion 13 to be held by the fixed housing 30, a movable-side holding target portion 14 to be held by the movable housing 40, and an elastically-displaceable elastic portion 15 provided between the fixed-side holding target portion 13 and the movable-side holding target portion 14.

The signal connection portion 11 extends rearward (Y2 direction) in the front-rear direction (Y-axis direction), and is solderable to a corresponding circuit portion of the circuit board P1. The fixed-side holding target portion 13 is bent at a front end portion (Y1-side end portion) of the signal connection portion 11, and extends to the X1 side (upward in FIG. 6A) in the coupling direction (X-axis direction). The fixed-side holding target portion 13 has a plurality of press-fitting protrusions 13A at both edge portions in a terminal width direction, that is, the same direction (Z-axis direction) as the terminal arrangement direction.

The elastic portion 15 couples end portions of the fixed-side holding target portion 13 and the movable-side holding target portion 14, and is elastically displaceable in the coupling direction (X-axis direction), the front-rear direction (Y-axis direction), and the terminal arrangement direction (Z-axis direction). The elastic portion 15 has a bent arm portion 15A bent in a substantially horizontal U-shape while extending from the fixed-side holding target portion 13, and a transition portion 15B extending in the X1 direction from the bent arm portion 15A.

The bent arm portion 15A is bent forward (Y1 direction), in the X1 direction, and rearward (Y2 direction) in this order while extending from a X1-side end portion of the fixed-side holding target portion 13, and is formed in the substantially horizontal U-shape opened rearward. The transition portion 15B is bent at an end portion of the bent arm portion 15A, extends in the X1 direction, and is coupled to the movable-side holding target portion 14. The elastic portion 15 has, at a center position in the terminal width direction, a slit 15C extending along the longitudinal direction of the elastic portion 15. Thus, the elastic portion 15 is elastically displaceable due to thin strips formed on both sides of the slit 15C, and as a result, a great amount of elastic displacement and therefore a great amount of floating of the movable housing 40 are easily ensured.

The movable-side holding target portion 14 is bent at an X1-side end portion of the transition portion 15B, and extends forward (Y1 side). The movable-side holding target portion 14 has a plurality of press-fitting protrusions 14A at both edge portions in the terminal width direction, that is, the same direction (Z-axis direction) as the terminal arrangement direction.

The signal contact arm portion 12 has a standing portion 12A bent at a front end portion of the movable-side holding target portion 14 and extending to the X1 side in the coupling direction, and a crank portion 12B extending forward in a crank shape from an X1-side end portion of the standing portion 12A.

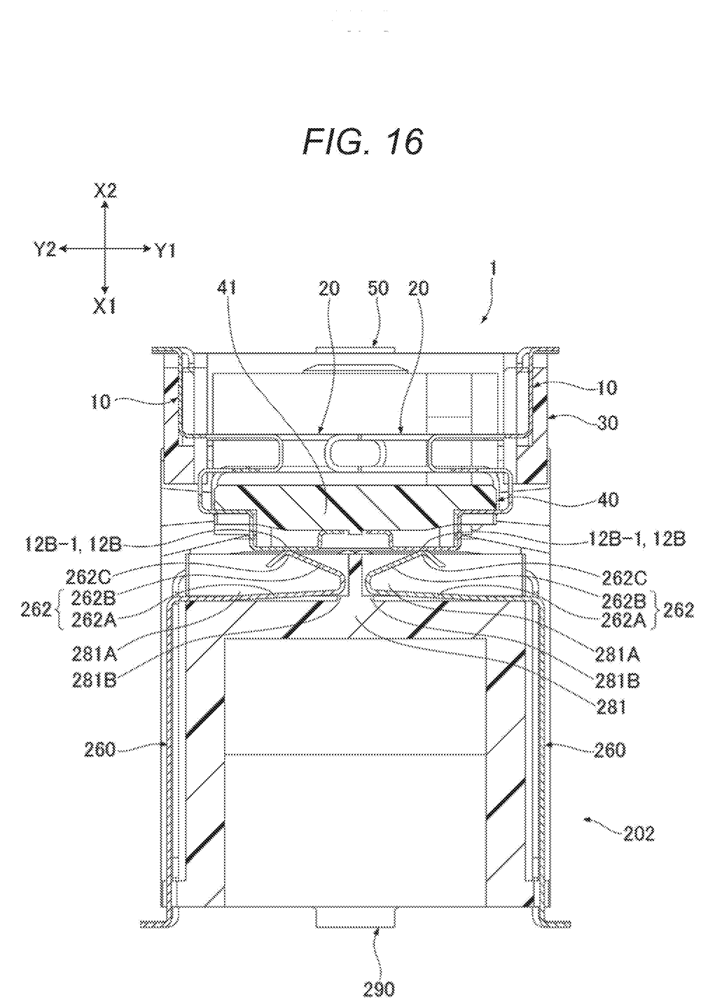

A portion of the crank portion 12B extending straight forward from the X1-side end portion of the standing portion 12A forms a signal contact portion 12B-1 contactable with the socket connector 202 at the X1-side plate surface. Specifically, the signal contact portion 12B-1 has a contact surface at the X1-side plate surface. With such a contact surface, the signal contact portion 12B-1 is contactable with a socket signal terminal 260 provided for the socket connector 202 with the coupling direction (X-axis direction) as a contact direction (see FIG. 16).

A portion of the crank portion 12B located forward (Y1 side) of the signal contact portion 12B-1 and on the X2 side in the coupling direction with respect to the signal contact portion 12B-1 and extending in the front-rear direction forms a support target portion 12B-2 to be supported by the movable housing 40. The support target portion 12B-2 formed on the free end side of the signal contact arm portion 12 in this manner is located on the X2 side with respect to the signal contact portion 12B-1. Thus, upon connector insertion and removal, the signal contact arm portion 12 is less likely to contact a free end portion of the mating terminal, that is, the socket signal terminal 260 provided for the socket connector 202. Consequently, deformation due to buckling of the signal contact arm portion 12 or the like can be favorably reduced.

Of the plug signal terminal 10, the fixed-side holding target portion 13 is press-fitted in and attached to the fixed housing 30 in the coupling direction (X-axis direction), and the movable-side holding target portion 14 is press-fitted in and attached to the movable housing 40 in the front-rear direction (Y-axis direction). As shown in FIG. 8A, the plug signal terminal 10 of the front (Y1-side) terminal line and the plug signal terminal 10 of the rear (Y2-side) terminal line are disposed without overlapping with each other in the front-rear direction (Y-axis direction) when viewed along the terminal arrangement direction (Z-axis direction).

FIG. 6B is a perspective view of the plug power terminal 20 alone. FIG. 6B shows the plug power terminal 20 of the rear (Y2-side) terminal line. Here, the configuration of the plug power terminal 20 of the rear (Y2-side) terminal line will be described based on FIG. 6B. The plug power terminal 20 of the front (Y1-side) terminal line has the same shape as that of the plug power terminal 20 shown in FIG. 6B, and therefore, the description thereof will be omitted.

The plug power terminal 20 has a greater terminal width dimension than that of the plug signal terminal 10. That is, the plug power terminal 20 is formed in such a manner that a metal band-shaped piece wider than the plug signal terminal 10 is bent in the plate thickness direction thereof. The plug power terminal 20 has a power connection portion 21 provided on one end side of the plug power terminal 20 and to be connected to the circuit board P1, a power contact arm portion 22 provided on the other end side of the plug power terminal 20 and configured to contact the socket connector 202 as the mating connector, a fixed-side holding target portion 23 to be held by the fixed housing 30, a movable-side holding target portion 24 to be held by the movable housing 40, and an elastically-displaceable elastic portion 25 provided between the fixed-side holding target portion 23 and the movable-side holding target portion 24.

The power connection portion 21 extends rearward (Y2 direction) in the front-rear direction (Y-axis direction), and is solderable to a corresponding circuit portion of the circuit board P1. The fixed-side holding target portion 23 is bent at a front end portion (Y1-side end portion) of the signal connection portion 11, and extends to the X1 side (upward in FIG. 6B) in the coupling direction. The fixed-side holding target portion 13 has a plurality of press-fitting protrusions 23A at both edge portions in a terminal width direction, that is, the same direction (Z-axis direction) as the terminal arrangement direction.

The elastic portion 25 couples end portions of the fixed-side holding target portion 23 and the movable-side holding target portion 24, and is elastically displaceable in the coupling direction (X-axis direction), the front-rear direction (Y-axis direction), and the terminal arrangement direction (Z-axis direction). The elastic portion 25 has a transition portion 25D extending in the X1 direction from an X1-side end portion of the fixed-side holding target portion 23, a bent arm portion 25A bent in a substantially horizontal U-shape while extending from the transition portion 25D, and a transition portion 25B extending in the X1 direction from the bent arm portion 25A.

The bent arm portion 25A is bent forward (Y1 direction), in the X1 direction, and rearward (Y2 direction) in this order while extending from an X1-side end portion of the transition portion 25D, and is formed in the substantially horizontal U-shape opened rearward. The transition portion 25B is bent at an end portion of the bent arm portion 25A, extends in the X1 direction, and is coupled to the movable-side holding target portion 24. The elastic portion 25 has, at a plurality of intermediate positions in the terminal width direction, slits 25C extending along the longitudinal direction of the elastic portion 25. Thus, the elastic portion 25 is elastically displaceable due to thin strips formed on both sides of each slit 25C, and as a result, a great amount of elastic displacement and therefore a great amount of floating of the movable housing 40 are easily ensured.

The movable-side holding target portion 24 is bent at an X1-side end portion of the transition portion 25B, and extends forward (Y1 side). The movable-side holding target portion 24 has a plurality of press-fitting protrusions 24A at both edge portions in the terminal width direction, that is, the same direction (Z-axis direction) as the terminal arrangement direction.

The power contact arm portion 22 has a standing portion 22A extending from a front end portion of the movable-side holding target portion 24 to the X1 side in the coupling direction, a power contact portion 22B extending forward of an end portion of the standing portion 22A, and an inclined portion 22C inclined while extending forward of an end portion of the power contact portion 22B.

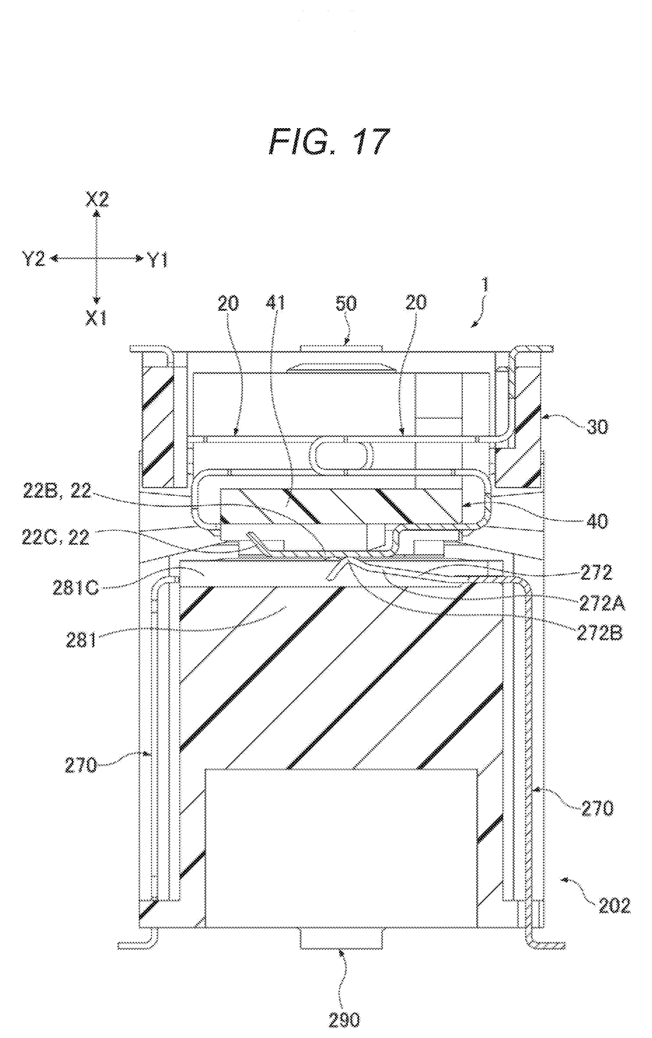

The power contact portion 22B extends straight, and at the X1-side plate surface thereof, is contactable with the socket connector 202. Specifically, the power contact portion 22B has a contact surface at the X1-side plate surface. With such a contact surface, the power contact portion 22B is contactable with a socket power terminal 270 provided for the socket connector 202 with the coupling direction (X-axis direction) as a contact direction (see FIG. 17). The inclined portion 22C is inclined to the X2 side while extending forward (Y1 side). The inclined portion 22C formed on the free end side of the power contact arm portion 22 is inclined to the X2 side in this manner, and therefore, the power contact arm portion 22 is less likely to contact a free end portion of the mating terminal, that is, the socket power terminal 270 provided for the socket connector 202, upon connector insertion and removal. Thus, deformation due to buckling of the power contact arm portion 22 or the like can be favorably reduced.

Of the plug power terminal 20, the fixed-side holding target portion 23 is press-fitted in and attached to the fixed housing 30 in the coupling direction (X-axis direction), and the movable-side holding target portion 24 is press-fitted in and attached to the movable housing 40 in the front-rear direction (Y-axis direction). As shown in FIGS. 4 and 7A, the two plug power terminals 20 provided at each end portion of the plug connector 1 are disposed with overlapping with each other in the front-rear direction (Y-axis direction) when viewed along the terminal arrangement direction (Z-axis direction). Specifically, as shown in FIGS. 4 and 7A, these plug power terminals 20 of the two terminal lines are disposed such that the power contact portions 22B of the power contact arm portions 22 overlap with each other in the front-rear direction. The power contact arm portion 22 is disposed in this manner, and therefore, an increase in the size of the plug connector 1 in the insertion-removal direction (Y-axis direction) can be avoided while each power contact arm portion 22 is extended and a great so-called spring length can be ensured. As shown in FIGS. 8A and 8B, the bent arm portions 25A of the elastic portions 25 are disposed with overlapping with each other in the front-rear direction. The elastic portion 25 is disposed in this manner, and therefore, an increase in the size of the plug connector 1 in the insertion-removal direction can be avoided while each elastic portion 25 is extended and a great so-called spring length is ensured. Thus, the amount of displacement, that is, the amount of floating, of the movable housing 40 can be increased.

The fixed housing 30 is made of an electric insulating material such as resin, and is formed in a quadrangular frame shape extending in the coupling direction (X-axis direction) with the terminal arrangement direction (Z-axis direction) as a longitudinal direction and the front-rear direction (Y-axis direction) as a lateral direction. As shown in FIGS. 4 and 5, the fixed housing 30 has two side walls 31 extending in the terminal arrangement direction, and two end walls 32 extending in the front-rear direction and coupling end portions of the side walls 31. The fixed housing 30 houses part of the movable housing 40 in an internal space 33 (see FIG. 5) surrounded by the two side walls 31 and the two end walls 32.

The side wall 31 has an intermediate wall 31A and coupling walls 31B. The intermediate wall 31A is located in an intermediate area including the terminal arrangement area in the terminal arrangement direction. The coupling walls 31B are located on both sides of the intermediate wall 31A in the terminal arrangement direction, and couple the intermediate wall 31A and the end walls 32.

As shown in FIG. 5, the intermediate wall 31A is formed with a plurality of fixed-side narrow grooves 31C for holding the plug signal terminals 10 at equal intervals in the area where the plug signal terminals 10 are arranged. Moreover, the intermediate wall 31A is formed with one fixed-side wide groove 31D for holding the plug power terminals 20 on each side of the area where the plug signal terminals 10 are arranged. The fixed-side narrow groove 31C and the fixed-side wide groove 31D are recessed from the inner surface of the intermediate wall 31A, extend in the coupling direction (X-axis direction), and at X2-side end portions thereof, are opened. The fixed-side narrow groove 31C receives the fixed-side holding target portion 13 of the plug signal terminal 10 from the X2 side, and such a fixed-side holding target portion 13 is press-fitted and held therein. The fixed-side wide groove 31D has a greater groove width (width in the terminal arrangement direction) than that of the fixed-side narrow groove 31C. The fixed-side wide groove 31D receives the fixed-side holding target portions 23 of the plug power terminals 20 from the X2 side, and such fixed-side holding target portions 23 are press-fitted and held therein.

As shown in FIGS. 4 and 5, the end wall 32 has a restriction portion 32A and a metal fixture holding groove 32B. The restriction portion 32A protrudes to the internal space 33 from the inner surface of an X1-side end portion of the end wall 32 at an intermediate position in the front-rear direction (Y-axis direction). As shown in FIGS. 7A and 7B, the restriction portion 32A is located on the X1 side with respect to a restriction target portion 44B provided for the movable housing 40, and is locked to the restriction target portion 44B from the X1 side to restrict movement of the movable housing 40 in the X1 direction by a predetermined amount or more. The end wall 32 has, at an intermediate position in the front-rear direction, the metal fixture holding groove 32B for holding the plug metal fixture 50. The metal fixture holding groove 32B is recessed from the outer surface of the end wall 32, is formed in a T-shape when viewed along the coupling direction (X-axis direction), and penetrates the end wall 32 in the coupling direction. The metal fixture holding groove 32B receives the plug metal fixture 50 from the X1 side, and such a plug metal fixture 50 is press-fitted and held therein.

The movable housing 40 is made of an electric insulating material such as resin, and houses part (lower portion in FIG. 4) of the movable housing 40 in the internal space 33 (see FIG. 5) of the fixed housing 30. As shown in FIGS. 4 and 5, the movable housing 40 has a base wall 41 extending in the terminal arrangement direction, end walls 42 extending in the X2 direction in the coupling direction from both end portions of the base wall 41 in the terminal arrangement direction, guide locking projections 43 as first guide locking portions protruding outward along the terminal arrangement direction from both end portions of the base wall 41 in the terminal arrangement direction, and bulges 44 bulging outward along the terminal arrangement direction from the end walls 42.

As shown in FIG. 5, the base wall 41 has, in the area where the plug signal terminals 10 are arranged, a plurality of narrow holding grooves 41A and a plurality of narrow housing grooves 41B. The narrow holding groove 41A is configured to hold the movable-side holding target portion 14 of the plug signal terminal 10, and the narrow housing groove 41B is configured to house the crank portion 12B of the plug signal terminal 10. As shown in FIG. 8A, the narrow holding groove 41A and the narrow housing groove 41B are recessed from the X1-side surface of the base wall 41, and extend in the front-rear direction (Y-axis direction). The plurality of narrow holding grooves 41A and the plurality of narrow housing grooves 41B are formed so as to be arranged in two lines in the front-rear direction and be arranged at equal intervals in the terminal arrangement direction. As shown in FIG. 8A, the narrow holding grooves 41A are formed in a front end portion (Y1-side end portion) and a rear end portion (Y2-side end portion) of the base wall 41. The narrow housing groove 41B is formed on the X1 side with respect to the narrow holding groove 41A in the coupling direction (X-axis direction) and inside the narrow holding groove 41A in the front-rear direction (Y-axis direction).

The narrow holding groove 41A receives the movable-side holding target portion 14 of the plug signal terminal 10 from the outside in the front-rear direction, and such a movable-side holding target portion 14 is press-fitted and held therein. In this state, as shown in FIG. 8A, the movable-side holding target portion 14 is supported from the X2 side by a groove bottom portion of the narrow holding groove 41A. The narrow housing groove 41B receives the crank portion 12B of the plug signal terminal 10 from the outside in the front-rear direction, and such a crank portion 12B is housed therein. In this state, as shown in FIG. 8A, the signal contact portion 12B-1 of the crank portion 12B is located with a gap from a groove bottom portion of the narrow housing groove 41B in the coupling direction (X-axis direction), and the support target portion 12B-2 of the crank portion 12B is supported from the X2 side by the groove bottom portion of the narrow housing groove 41B.

As shown in FIG. 5, the base wall 41 has, in the area where the plug power terminals 20 are arranged, a plurality of wide housing grooves 41C. The wide housing groove 41C is configured to house the movable-side holding target portion 24 and power contact arm portion 22 of the plug power terminal 20. Two wide housing grooves 41C are formed on each of the Z1 side and Z2 side of the area where the plug signal terminals 10 are arranged. The wide housing groove 41C is recessed from the X1-side surface of the base wall 41, extends in the front-rear direction (Y-axis direction), and penetrates the base wall 41.

The wide housing groove 41C has a wide holding groove 41C-1 for holding the movable-side holding target portion 24 on any one of the front end side (Y1 side) or the rear end side (Y2 side) in the front-rear direction (Y-axis direction).

Specifically, as shown in FIGS. 4 and 5, the two wide housing grooves 41C are arranged at each of Z1-side and Z2-side end portions of the base wall 41. Of the two wide housing grooves 41C at the Z1-side end portion of the base wall 41, the wide housing groove 41C located outside (Z1 side) in the terminal arrangement direction is formed with the wide holding groove 41C-1 on the front side (Y1 side), and the wide housing groove 41C located inside (Z2 side) in the terminal arrangement direction is formed with the wide holding groove 41C-1 on the rear side (Y2 side), as shown in FIG. 7A. Of the two wide housing grooves 41C at the Z2-side end portion of the base wall 41, the wide housing groove 41C located outside (Z2 side) in the terminal arrangement direction is formed with the wide holding groove 41C-1 on the rear side (Y2 side), and the wide housing groove 41C located inside (Z1 side) in the terminal arrangement direction is formed with the wide holding groove 41C-1 on the front side (Y1 side).

As shown in FIG. 8B, the wide holding groove 41C-1 extends in the front-rear direction (Y-axis direction) along the groove bottom surface of the wide housing groove 41C. The wide holding groove 41C-1 receives the movable-side holding target portion 24 of the plug power terminal 20 from the outside in the front-rear direction, and such a movable-side holding target portion 24 is press-fitted and held therein.

The wide housing groove 41C receives the movable-side holding target portion 24 and power contact arm portion 22 of the plug power terminal 20 from one side in the front-rear direction, specifically the side on which the wide holding groove 41C-1 is located. In this state, as shown in FIG. 8B, the movable-side holding target portion 24 is supported from the X2 side by a groove bottom portion of the wide holding groove 41C-1. Moreover, the wide housing groove 41C houses the power contact arm portion 22. In this state, as shown in FIG. 8B, the power contact arm portion 22 is located with a gap from a groove bottom portion of the wide housing groove 41C in the coupling direction (X-axis direction).

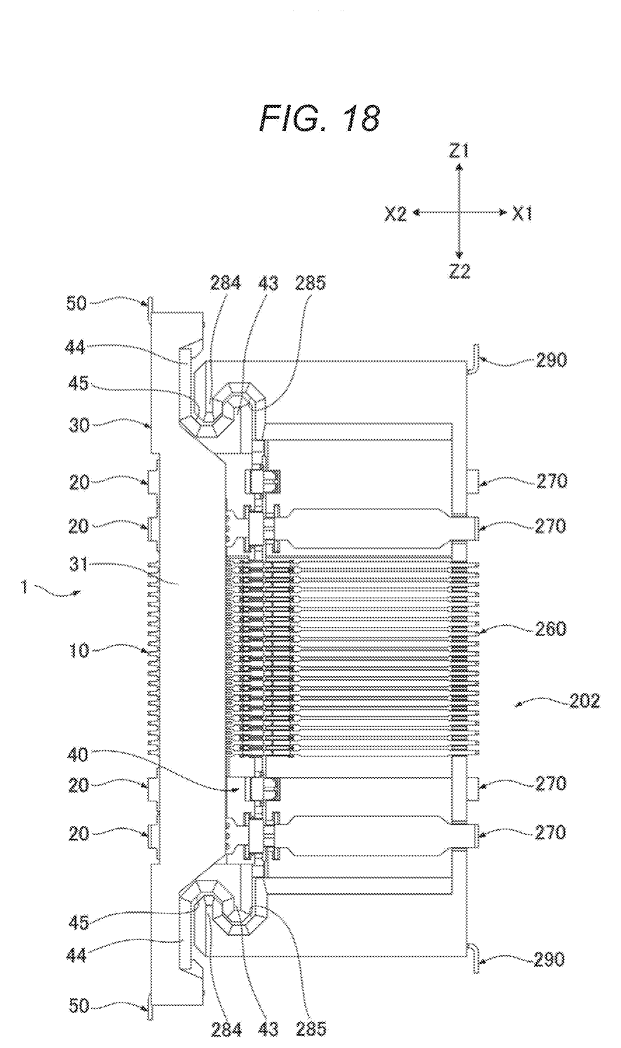

As shown in FIGS. 4 and 5, the guide locking projections 43 protrude outward along the terminal arrangement direction from both end portions of the base wall 41 in the terminal arrangement direction, and extend in the front-rear direction. The guide locking projection 43 and the socket connector 202 guide each other in the front-rear direction, and are locked to each other in the coupling direction. Specifically, in the course of the connector fitting connection, the guide locking projection 43 enters a guide locking groove 285, which is provided as a second guide locking portion, of the socket connector 202, and the guide locking projection 43 and the groove inner surface of the guide locking groove 285 guide each other in the front-rear direction. In the connector fitting connection state, the guide locking projection 43 and the groove inner surface of the guide locking groove 285 are locked to each other in the coupling direction (see FIG. 18).

As shown in FIG. 5, the bulge 44 bulges outward of an X2-side end portion of the end wall 42 along the terminal arrangement direction, and extends in the front-rear direction. The bulge 44 is located with a gap from the guide locking projection 43 on the X2 side with respect to the guide locking projection 43 in the coupling direction, and bulges outward of the guide locking projection 43 in the terminal arrangement direction. An outer end portion of the bulge 44 in the terminal arrangement direction is formed, at an intermediate position in the front-rear direction, an end recess 44A recessed from the X1-side surface of the bulge 44 and the restriction target portion 44B located on the X2 side with respect to the end recess 44A. As shown in FIG. 7B, the end recess 44A houses part of the restriction portion 32A of the fixed housing 30. The restriction target portion 44B is located on the X2 side (immediately below in FIG. 7B) with respect to the restriction portion 32A, and faces the restriction portion 32A from the X2 side.

As shown in FIGS. 4, 5, and 7B, a guide locking groove 45 as the first guide locking portion opened outward along the terminal arrangement direction and extending in the front-rear direction is formed between the guide locking projection 43 and the bulge 44 in the coupling direction. The guide locking groove 45 and the socket connector 202 guide each other in the front-rear direction, and are locked to each other in the coupling direction. Specifically, in the course of the connector fitting connection, the guide locking groove 45 receives a guide locking projection 284, which is provided as the second guide locking portion, of the socket connector 202, and the groove inner surface of the guide locking groove 45 and the guide locking projection 284 guide each other in the front-rear direction. Moreover, in the connector fitting connection state, the groove inner surface of the guide locking groove 45 and the guide locking projection 284 are locked to each other in the coupling direction (see FIG. 18).

The guide locking groove 45 extends over the entire area of the movable housing 40 in the front-rear direction, and is opened at the front and rear ends. Thus, the guide locking groove 45 can receive the guide locking projection 284 of the socket connector 202 from any of the front and rear sides.

As shown in FIGS. 4 and 5, the plug metal fixture 50 is formed in such a manner that a metal plate member is bent in the plate thickness direction thereof. The plug metal fixture 50 has a holding target plate portion 51 with a plate surface perpendicular to the terminal arrangement direction, and a fixing portion 52 bent at an X2-side end portion of the holding target plate portion 51 and extending outward along the terminal arrangement direction. The holding target plate portion 51 is press-fitted in the metal fixture holding groove 32B of the fixed housing 30 from the X1 side, and at both side edge portions (edge portions extending in the coupling direction) thereof, is held by the metal fixture holding groove 32B. The fixing portion 52 is fixed to a corresponding portion of the circuit board P1 by soldering.

The plug connector 1 is assembled in the following manner. First, the movable-side holding target portion 14 of the plug signal terminal 10 is press-fitted in the narrow holding groove 41A of the movable housing 40 in the front-rear direction, and in this manner, the plug signal terminal 10 is attached to the movable housing 40. That is, the plug signal terminals 10 of the front (Y1-side) terminal line are attached from the front, and the plug signal terminals 10 of the rear (Y2-side) terminal line are attached from the rear. At this time, the crank portion 12B of the signal contact arm portion 12 of the plug signal terminal 10 is housed in the narrow housing groove 41B, and the support target portion 12B-2 is supported by the groove bottom portion of the narrow housing groove 41B.

The movable-side holding target portion 24 of the plug power terminal 20 is press-fitted in the wide housing groove 41C of the movable housing 40 in the front-rear direction, and in this manner, the plug power terminal 20 is attached to the movable housing 40. At this time, the plug power terminals 20 located outside the Z1-side end portion of the base wall 41 and inside the Z2-side end portion of the base wall 41 are attached from the front, and the plug power terminals 20 located inside the Z1-side end portion of the base wall 41 and outside the Z2-side end portion of the base wall 41 are attached from the rear. The plug power terminal 20 is attached in this manner, and therefore, the power contact arm portion 22 is also housed in the wide housing groove 41C together with the movable-side holding target portion 24. Either a step of attaching the plug signal terminals 10 or a step of attaching the plug power terminals 20 may be performed first, or these steps may be performed simultaneously.

Next, the fixed housing 30 is attached to the movable housing 40 and the plug terminals 10, 20 from the X1 side, and in this manner, the plug terminals 10, 20 are attached to the fixed housing 30. Specifically, the fixed-side holding target portion 13 of the plug signal terminal 10 is press-fitted in and attached to the fixed-side narrow groove 31C of the fixed housing 30 from the X2 side in the coupling direction. Moreover, the fixed-side holding target portion 23 of the plug power terminal 20 is press-fitted in and attached to the fixed-side wide groove 31D of the fixed housing 30 from the X2 side in the coupling direction. Along with attachment of the plug terminals 10, 20 to the fixed housing 30, the movable housing 40 enters the internal space 33 of the fixed housing 30 from the X2 side, and part of the movable housing 40 is housed in the internal space 33.

Next, the holding target plate portion 51 of the plug metal fixture 50 is press-fitted in the metal fixture holding groove 32B of the fixed housing 30 from the X1 side, and in this manner, the plug metal fixture 50 is attached to the fixed housing 30. Note that a step of attaching the plug metal fixtures 50 may be performed before or at the same time as a step of attaching the plug terminals 10, 20 to the fixed housing 30. The plug terminals 10, 20 and the plug metal fixtures 50 are attached to the plug housing, and in this manner, the assembly of the plug connector 1 is completed.

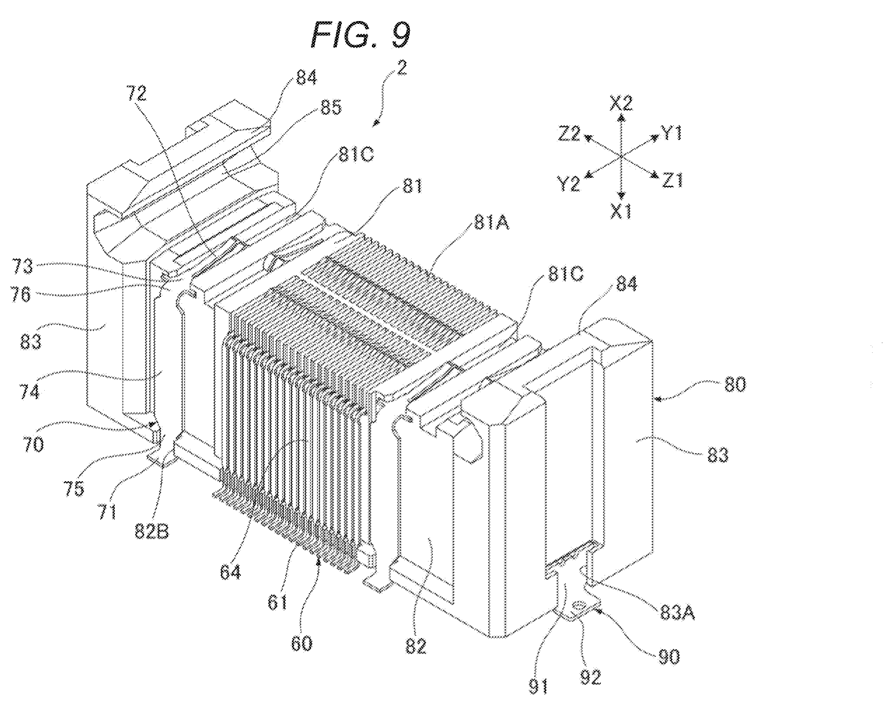

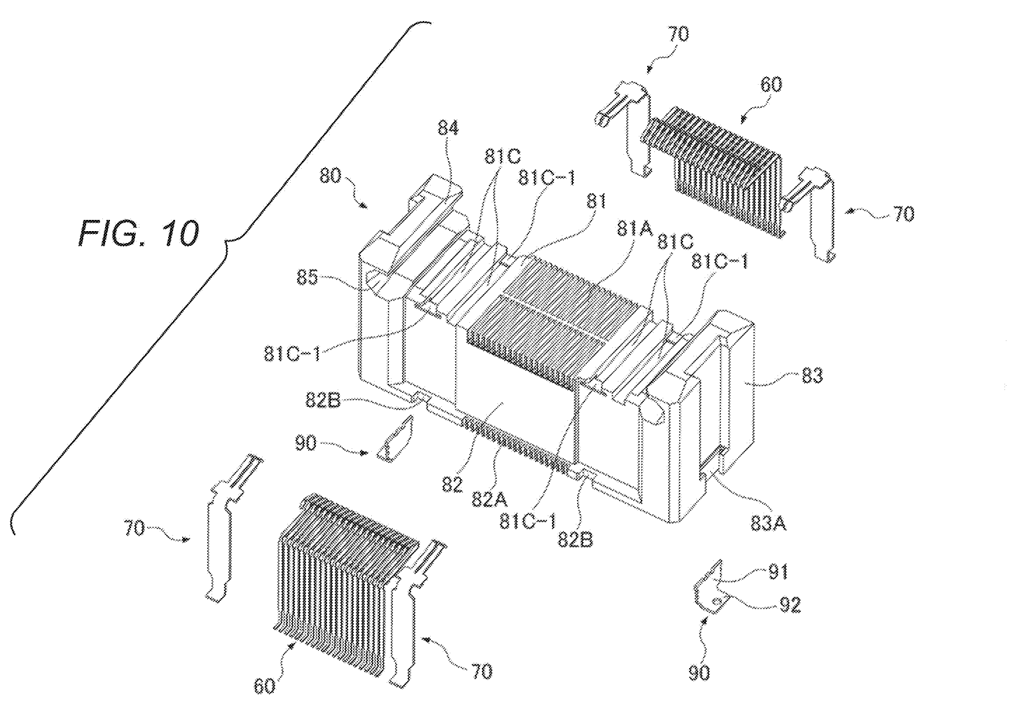

As shown in FIGS. 9 and 10, the socket connector 2 has a plurality of socket signal terminals 60, a plurality of socket power terminals 70, a plurality of socket metal fixtures 90, and a socket housing 80. The plurality of socket signal terminals 60, the plurality of socket power terminals 70, and the plurality of socket metal fixtures 90 are held by the socket housing 80. In the following description, the socket signal terminal 60 and the socket power terminal 70 may be referred to as a socket terminal(s) 60, 70.

As shown in FIGS. 9 and 10, the plurality of socket terminals 60, 70 is arranged with the direction (Z-axis direction) perpendicular to both the coupling direction (X-axis direction) and the front-rear direction (Y-axis direction) as the terminal arrangement direction. The socket terminal 60, 70 is formed in such a manner that a metal band-shaped piece is bent in the plate thickness direction thereof. The socket terminal 60, 70 is disposed in such a posture that the plate surface thereof is perpendicular to the terminal arrangement direction.

The socket terminals 60, 70 are arranged so as to form two terminal lines, specifically a rear terminal line and a front terminal line. Here, the “front terminal line” is formed of the socket terminals 60, 70 attached to the socket housing 80 from the rear (Y2 side). The “rear terminal line” is formed of the socket terminals 60, 70 attached to the socket housing 80 from the front (Y1 side). Note that in the present embodiment, the terminal lines of the socket terminals 60, 70 are mating terminal lines corresponding to the terminal lines of the plug terminals 10, 20.

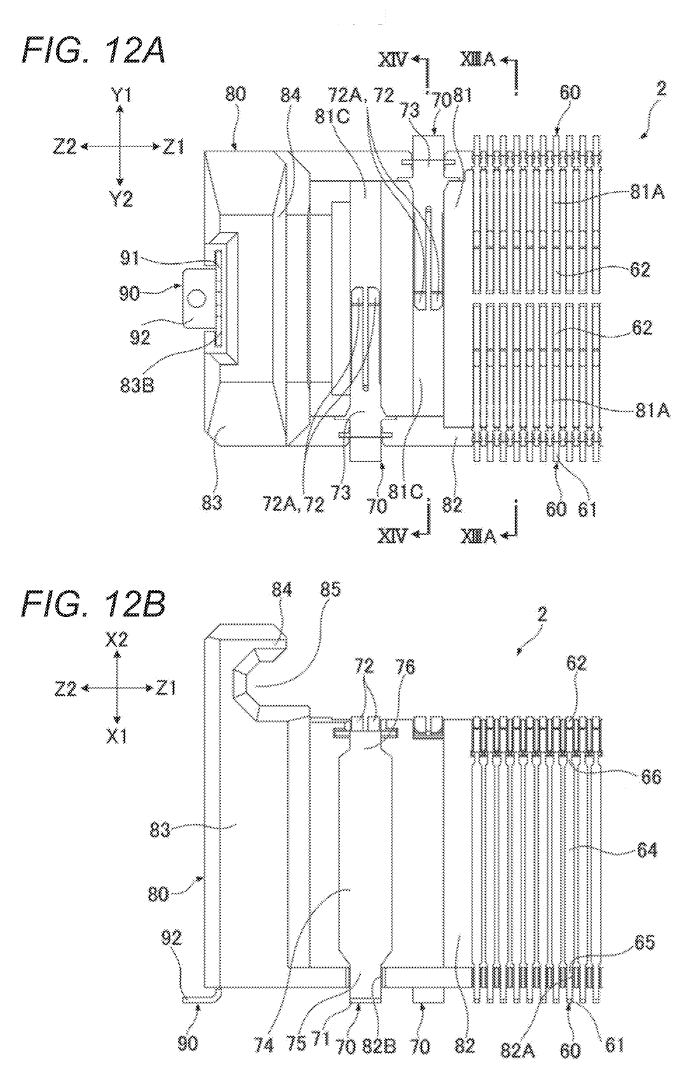

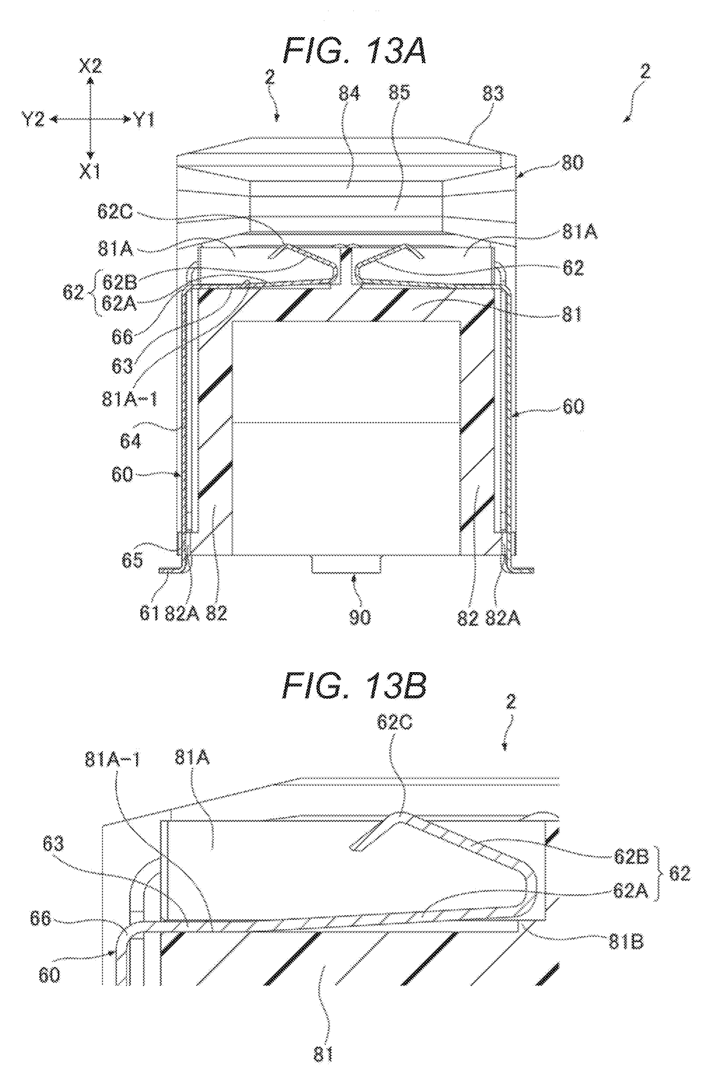

As shown in FIG. 10, the socket signal terminals 60 of the two terminal lines are disposed in postures symmetrical in the front-rear direction at the same positions in the terminal arrangement direction (also see FIGS. 12A and 13A). The socket signal terminals 60 are disposed in the two terminal lines as described above, and therefore, an increase in the size of the socket connector 2 in the terminal arrangement direction can be suppressed to the minimum while the number of socket signal terminals 60 is increased.

As shown in FIGS. 9 and 10, two socket power terminals 70 are disposed on each side of the area where the socket signal terminals 60 are arranged in the terminal arrangement direction. Here, on each side, the socket power terminals 70 attached to the socket housing 80 from the rear are included in the rear terminal line, and the socket power terminals 70 attached to the socket housing 80 from the front are included in the front terminal line. Moreover, on each side, the two socket power terminals 70 are disposed in postures symmetrical in the front-rear direction at different positions in the terminal arrangement direction.

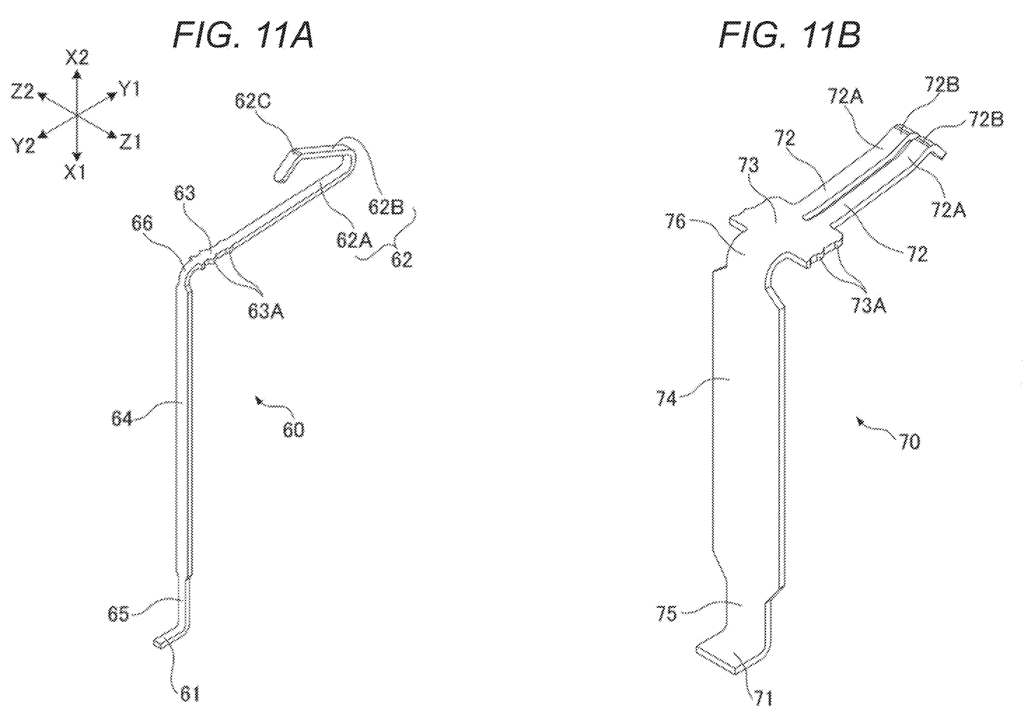

FIG. 11A is a perspective view of the socket signal terminal 60 alone. FIG. 11A shows the socket signal terminal 60 of the rear (Y2-side) terminal line. Here, the configuration of the socket signal terminal 60 of the rear (Y2-side) terminal line will be described based on FIG. 11A. The socket signal terminal 60 of the front (Y1-side) terminal line has the same shape as that of the socket signal terminal 60 shown in FIG. 11A, and therefore, the description thereof will be omitted.

The socket signal terminal 60 has a signal connection portion 61 provided on one end side of the socket signal terminal 60 and to be connected to the circuit board P1, a signal contact arm portion 62 as a contact portion provided on the other end side of the socket signal terminal 60 and configured to contact the plug connector 301 as the mating connector, a holding target portion 63 to be held by the socket housing 80, a leg 64 provided between the signal connection portion 61 and the holding target portion 63, a transition portion 65 coupling the signal connection portion 61 and the leg 64, and a transition portion 66 coupling the holding target portion 63 and the leg 64.

The signal connection portion 61 extends rearward (Y2 direction) in the front-rear direction (Y-axis direction), and is solderable to a corresponding circuit portion of the circuit board P1. The transition portion 65, the leg 64, and the transition portion 66 are continuously provided in this order from the X1 side to the X2 side, and extend in the coupling direction (X-axis direction). Specifically, the transition portion 65 is bent at a front end portion (Y1-side end portion) of the signal connection portion 61, and extends in the X2 direction in the coupling direction (X-axis direction). The leg 64 extends straight in the X2 direction from an X2-side end portion of the transition portion 65. The leg 64 is formed larger, that is, wider, in the terminal arrangement direction (Z-axis direction) than the transition portion 65 which is a portion continuous to an X1-side end portion of the leg 64 and the transition portion 66 which is a portion continuous to an X2-side end portion of the leg 64. The transition portion 66 is bent at the X2-side end portion of the leg 64, extends forward (Y1 direction), and is coupled to the holding target portion 63.

The holding target portion 63 extends forward from a front end portion (Y1-side end portion) of the transition portion 66. The holding target portion 63 has a plurality of press-fitting protrusions 63A at both edge portions in a terminal width direction, that is, the same direction (Z-axis direction) as the terminal arrangement direction.

The signal contact arm portion 62 has a base arm portion 62A extending forward of a front end portion of the holding target portion 63, and a folded arm portion 62B folded back at a front end portion of the base arm portion 62A and extending rearward. The base arm portion 62A and the folded arm portion 62B are both elastically displaceable in the coupling direction (X-axis direction).

As shown in FIGS. 13A and 13B, the base arm portion 62A is inclined to the X2 side while extending forward. The folded arm portion 62B is a portion for contact with the plug connector 301, and is located on the X2 side with respect to the base arm portion 62A and inclined to the X2 side while extending rearward. The folded arm portion 62B has, on the rear end side thereof, a signal contact 62C bent so as to protrude to the X2 side, and at the signal contact 62C, contacts a plug signal terminal provided for the plug connector 301. Here, the signal contact 62C has a contact surface at the X2-side surface, and is contactable with the plug signal terminal of the plug connector 301 with the coupling direction (X-axis direction) as a contact direction.

The holding target portion 63 of the socket signal terminal 60 is press-fitted in and attached to the socket housing 80 in the front-rear direction (Y-axis direction). As shown in FIG. 13A, the socket signal terminal 60 of the front terminal line and the socket signal terminal 60 of the rear terminal line are disposed without overlapping with each other in the front-rear direction (Y-axis direction) when viewed along the terminal arrangement direction (Z-axis direction). Moreover, in the present embodiment, a distance in the front-rear direction between the signal contact 62C in the front terminal line and the signal contact 62C in the rear terminal line is set greater than the length (dimension in the front-rear direction) of the signal contact portion 12B-1 of the plug signal terminal 10.

FIG. 11B is a perspective view of the socket power terminal 70 alone. FIG. 11B shows the socket power terminal 70 of the rear (Y2-side) terminal line. Here, the configuration of the socket power terminal 70 of the rear (Y2-side) terminal line will be described based on FIG. 11B. The socket power terminal 70 of the front (Y1-side) terminal line has the same shape as that of the socket power terminal 70 shown in FIG. 11B, and therefore, the description thereof will be omitted.

The socket power terminal 70 has a greater terminal width dimension that that of the socket signal terminal 60. That is, the socket power terminal 70 is formed in such a manner that a metal band-shaped piece wider than the socket signal terminal 60 is bent in the plate thickness direction thereof. The socket power terminal 70 has a power connection portion 71 provided on one end side of the socket power terminal 70 and to be connected to the circuit board P1, two power contact arm portions 72 provided on the other end side of the socket power terminal 70 and configured to contact the plug connector 301 as the mating connector, a holding target portion 73 to be held by the socket housing 80, a leg 74 provided between the power connection portion 71 and the holding target portion 73, a transition portion 75 coupling the power connection portion 71 and the leg 74, and a transition portion 76 coupling the holding target portion 73 and the leg 74.

The power connection portion 71 extends rearward (Y2 direction) in the front-rear direction (Y-axis direction), and is solderable to a corresponding circuit portion of the circuit board P1. The transition portion 75, the leg 74, and the transition portion 76 are continuously provided in this order from the X1 side to the X2 side, and extends in the coupling direction (X-axis direction). Specifically, the transition portion 75 is bent at a front end portion (Y1-side end portion) of the power connection portion 71, and extends in the X2 direction. The leg 74 extends straight in the X2 direction from an X2-side end portion of the transition portion 75. The leg 74 is formed larger, that is, wider, in the terminal arrangement direction (Z-axis direction) than the transition portion 75 which is a portion continuous to an X1-side end portion of the leg 74 and the transition portion 76 which is a portion continuous to an X2-side end portion of the leg 74. The transition portion 76 is bent at the X2-side end portion of the leg 74, extends forward (Y1 direction), and is coupled to the holding target portion 73.

The holding target portion 73 extends forward from a front end portion (Y1-side end portion) of the transition portion 76. The holding target portion 73 has a plurality of press-fitting protrusions 73A at both edge portions in a terminal width direction, that is, the same direction (Z-axis direction) as the terminal arrangement direction.

The two power contact arm portions 72 are provided adjacent to each other in the terminal width direction, and extend forward from a front end portion of the holding target portion 73. The power contact arm portion 72 is inclined to the X2 side while extending forward, and on the front end side thereof, has the power contact portion 72A provided for contact with the plug connector 301. The power contact portion 72A has a power contact 72B bent so as to protrude to the X2 side, and at the power contact 72B, contacts a plug power terminal provided for the plug connector 301. Here, the power contact 72B has a contact surface at the X2-side surface, and is contactable with the plug power terminal of the plug connector 301 with the coupling direction (X-axis direction) as a contact direction.

The holding target portion 73 of the socket power terminal 70 is press-fitted in and attached to the socket housing 80 in the front-rear direction (Y-axis direction). As shown in FIGS. 9 and 12A, the two socket power terminals 70 each provided at the end portions of the socket connector 2 are disposed with overlapping with each other in the front-rear direction (Y-axis direction) when viewed along the terminal arrangement direction (Z-axis direction). Specifically, these socket power terminals 70 of the two terminal lines are disposed such that the power contact portions 72A of the power contact arm portions 72 overlap with each other in the front-rear direction, as shown in FIGS. 9 and 12A. The power contact arm portion 72 is disposed in this manner, and therefore, an increase in the size of the socket connector 2 in the insertion-removal direction (Y-axis direction) can be avoided while each power contact arm portion 72 is extended and a great so-called spring length is ensured.

The socket housing 80 is made of an electric insulating material such as resin, and is formed with a substantially rectangular parallelepiped outer shape with the terminal arrangement direction (Z-axis direction) as a longitudinal direction, the front-rear direction (Y-axis direction) as a lateral direction, and the coupling direction (X-axis direction) as a height direction. As shown in FIGS. 9 and 10, the socket housing 80 has a base wall 81 extending in the terminal arrangement direction, two side walls 82 extending in the X1 direction from side edge portions (edge portions extending in the terminal arrangement direction) of the base wall 81, two end walls 83 extending in the X1 direction and the X2 direction from end edge portions (edge portions extending in the front-rear direction) of the base wall 81, and guide locking projections 84 as second guide locking portions protruding inward of X2-side end portions of the end walls 83 along the terminal arrangement direction.

As shown in FIGS. 9 and 10, the base wall 81 has, in the area where the socket signal terminals 60 are arranged, a plurality of narrow housing grooves 81A. The narrow housing groove 81A is configured to house the holding target portion 63 and signal contact arm portion 62 of the socket signal terminal 60. As shown in FIGS. 13A, the narrow housing groove 81A is recessed from the X2-side surface of the base wall 81, and extends in the front-rear direction. The plurality of narrow housing grooves 81A is formed so as to be arranged in two lines in the front-rear direction and be arranged at equal intervals in the terminal arrangement direction.

In a state of the holding target portion 63 and the signal contact arm portion 62 being housed in the narrow housing groove 81A, the signal contact arm portion 62 is located with a gap from a groove bottom portion of the narrow housing groove 81A. With this configuration, the signal contact arm portion 62 is elastically displaceable in the coupling direction (X-axis direction). When the signal contact arm portion 62 is in a free state, the signal contact 62C is located so as to protrude from the narrow housing groove 81A.

As shown in FIGS. 13A and 13B, the narrow housing groove 81A has, on the outer end side (end side closer to the side wall 82 in the front-rear direction) thereof in the front-rear direction, a narrow holding groove 81A-1 for holding the holding target portion 63. The narrow holding groove 81A-1 extends in the front-rear direction along the groove bottom surface of the narrow housing groove 81A. The narrow holding groove 81A-1 receives the holding target portion 63 of the socket signal terminal 60 from the outside in the front-rear direction, and such a holding target portion 63 is press-fitted and held therein. In this state, as shown in FIGS. 13A and 13B, the holding target portion 63 is supported from the X1 side by a groove bottom portion of the narrow holding groove 81A-1.

As shown in FIG. 13B, in the narrow housing groove 81A, a stopper 81B protruding from the groove bottom surface of the narrow housing groove 81A is formed on the inner end side (end side closer to the center position of the base wall 81 in the front-rear direction) in the front-rear direction. The stopper 81B contacts the signal contact arm portion 62 of the socket signal terminal 60 in the coupling direction (X-axis direction), thereby restricting excessive elastic displacement of the signal contact arm portion 62 beyond a predetermined amount.

The stopper 81B is provided in the narrow housing groove 81A in this manner, and therefore, excessive displacement of the signal contact arm portion 62 of the socket signal terminal 60 to deep in the narrow housing groove 81A due to external force can be reduced. Specifically, the signal contact arm portion 62 contacts the stopper 81B, and therefore, further displacement of the signal contact arm portion 62 is restricted. Thus, damage to the signal contact arm portion 62 due to excessive displacement can be favorably reduced.

As shown in FIGS. 9 and 10, the base wall 81 has, in the area where the socket power terminals 70 are arranged, a plurality of wide housing grooves 81C. The wide housing groove 81C is configured to house the holding target portion 73 and power contact arm portion 72 of the socket power terminal 70. Two wide housing grooves 81C are formed on each of the Z1 side and the Z2 side with respect to the area where the socket signal terminals 60 are arranged. The wide housing groove 81C is recessed from the X2-side surface of the base wall 81, extends in the front-rear direction, and penetrates the base wall 81.

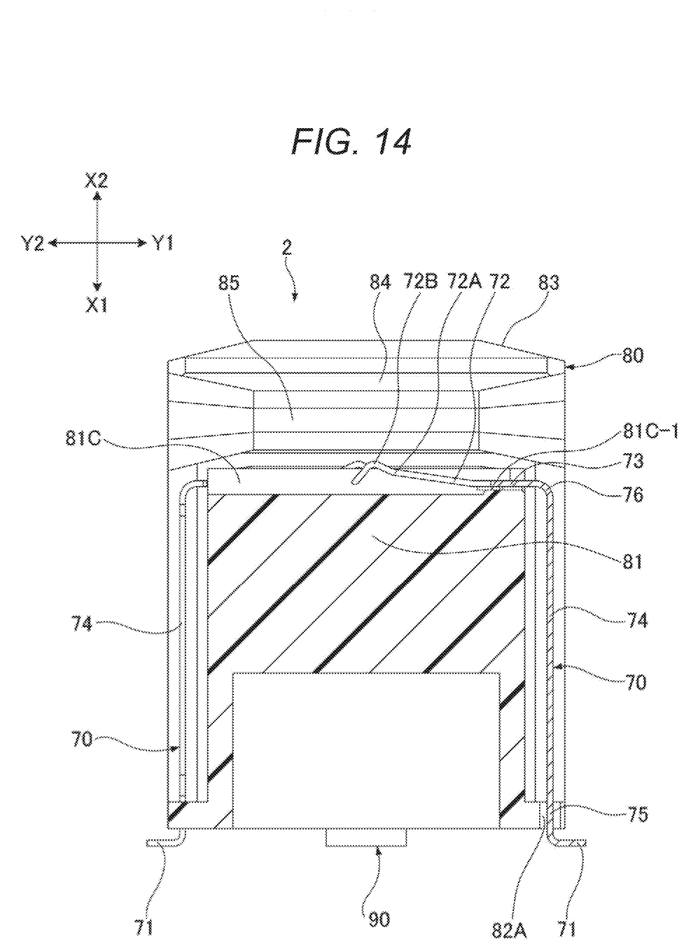

As shown in FIGS. 10 and 14, the wide housing groove 81C has a wide holding groove 81C-1 for holding the holding target portion 73 on any one of the front end side (Y1 side) or the rear end side (Y2 side) in the front-rear direction.

Specifically, as shown in FIGS. 9 and 10, the wide housing grooves 81C are arranged at each of Z1-side and Z2-side end portions of the base wall 81. Of the two wide housing grooves 81C at the Z1-side end portion of the base wall 81, the wide housing groove 81C located outside (Z1 side) in the terminal arrangement direction is formed with the wide holding groove 81C-1 on the front side (Y1 side), and the wide housing groove 81C located inside (Z2 side) in the terminal arrangement direction is formed with the wide holding groove 81C-1 on the rear side (Y2 side). Of the two wide housing grooves 81C at the Z2-side end portion of the base wall 81, the wide housing groove 81C located outside (Z2 side) in the terminal arrangement direction is formed with the wide holding groove 81C-1 on the rear side (Y2 side), and the wide housing groove 81C located inside (Z1 side) in the terminal arrangement direction is formed with the wide holding groove 81C-1 on the front side (Y1 side), as shown in FIG. 12A.

The wide holding groove 81C-1 extends in the front-rear direction along the groove bottom surface of the wide housing groove 81C. The wide holding groove 81C-1 receives the holding target portion 73 of the plug power terminal 20 from the outside in the front-rear direction, and such a holding target portion 73 is press-fitted and held therein.

The wide housing groove 81C receives the holding target portion 73 and power contact arm portion 72 of the socket power terminal 70 from one side in the front-rear direction, specifically the side on which the wide holding groove 81C-1 is located. In this state, as shown in FIG. 14, the holding target portion 73 is supported from the X1 side by a groove bottom portion of the wide holding groove 81C-1. Moreover, the wide housing groove 81C houses the power contact arm portion 72. In this state, as shown in FIG. 14, the power contact arm portion 72 is located with a gap from a groove bottom portion of the wide housing groove 81C. With this configuration, the power contact arm portion 72 is elastically displaceable in the coupling direction (X-axis direction) in the area of the gap. When the power contact arm portion 72 is in a free state, the power contact 72B is located so as to protrude from the wide housing groove 81C.

As shown in FIG. 10, most part of the outer surface of the side wall 82 other than an X1-side end portion (lower end portion in FIG. 10) is located inside with respect to the outer surface of the end wall 83 in the front-rear direction (Y-axis direction). The outer surface of the side wall 82 in the area where the socket power terminals 70 are arranged is located inside the outer surface in the area where the socket signal terminals 60 are arranged in the front-rear direction.

The side wall 82 has, at the X1-side end portion thereof, a plurality of narrow restriction grooves 82A. The plurality of narrow restriction grooves 82A is formed so as to be arranged in the terminal arrangement direction in the area where the socket signal terminals 60 are arranged. The narrow restriction groove 82A houses the transition portion 65 of the socket signal terminal 60, and by the groove inner surface thereof, restricts displacement of the transition portion 65 in the terminal arrangement direction. The side wall 82 has, at the X1-side end portion thereof, a plurality of wide restriction grooves 82B. The plurality of wide restriction grooves 82B is formed in the area where the socket power terminals 70 are arranged. The wide restriction groove 82B is formed wider than the narrow restriction groove 82A, houses the transition portion 75 of the socket power terminal 70, and by the groove inner surface thereof, restricts displacement of the transition portion 75 in the terminal arrangement direction.

As shown in FIGS. 9 and 10, the outer surface of an intermediate portion of the end wall 83 in the front-rear direction is recessed with respect to the outer surfaces of other portions. An X1-side end portion (lower end portion in FIGS. 9 and 10) of the end wall 83 is formed with a metal fixture holding groove 83A for holing the socket metal fixture 90. The metal fixture holding groove 83A is recessed from the outer surface of the end wall 32, is formed in a T-shape when viewed along the coupling direction (X-axis direction), and penetrates the X1-side end portion of the end wall 83 in the coupling direction. The metal fixture holding groove 83A receives the socket metal fixture 90 from the X2 side, and such a socket metal fixture 90 is press-fitted and held therein.

As shown in FIGS. 9 and 10, the end wall 83 extends to the X2 side (upward in FIGS. 9 and 10) with respect to the base wall 81 and the side wall 82. The guide locking projection 84 protrudes inward of an X2-side end portion (upper end portion in FIGS. 9 and 10) of the end wall 83 along the terminal arrangement direction, and extends in the front-rear direction. The guide locking projection 84 is located with a gap from the end wall 83 in the coupling direction.

The guide locking projection 84 and a guide locking groove of the plug connector 301 guide each other in the front-rear direction, and are locked to each other in the coupling direction. Specifically, the guide locking projection 84 enters the guide locking groove, which is provided as a first guide locking portion, of the plug connector 301 in the course of the connector fitting connection, and the guide locking projection 84 and the groove inner surface of the guide locking groove of the plug connector 301 guide each other in the front-rear direction. Moreover, the guide locking projection 84 and the groove inner surface of the guide locking groove of the plug connector 301 are locked to each other in the coupling direction in the connector fitting connection state.

As shown in FIGS. 9, 10, and 12B, a guide locking groove 85 as the second guide locking portion opened inward in the terminal arrangement direction and extending in the front-rear direction is formed between the guide locking projection 84 and the end wall 83 in the coupling direction. The guide locking groove 85 and a guide locking projection of the plug connector 301 guide each other in the front-rear direction, and the guide locking groove 85 and the plug connector 301 are locked to each other in the coupling direction. Specifically, the guide locking groove 85 receives the guide locking projection, which is provided as the first guide locking portion, of the plug connector 301 in the course of the connector fitting connection, and the groove inner surface of the guide locking groove 85 and the guide locking projection of the plug connector 301 guide each other in the front-rear direction. Moreover, the groove inner surface of the guide locking groove 85 and the guide locking projection of the plug connector 301 are locked to each other in the coupling direction in the connector fitting connection state.

The guide locking groove 85 extends over the entire area of the socket housing 80 in the front-rear direction, and is opened at the front and rear ends. Thus, the guide locking groove 85 can receive the guide locking projection of the plug connector 301 from any of the front and rear sides.

The socket metal fixture 90 is formed in such a manner that a metal plate member is bent in the plate thickness direction thereof. The socket metal fixture 90 has a holding target plate portion 91 having a plate surface perpendicular to the terminal arrangement direction, and a fixing portion 92 bent at an X1-side end portion of the holding target plate portion 91 and extending outward along the terminal arrangement direction. The holding target plate portion 91 is press-fitted in the metal fixture holding groove 83A from the X2 side, and both side edge portions (edge portions extending in the coupling direction) thereof are held by the metal fixture holding groove 83A. The fixing portion 92 is fixed to a corresponding portion of the circuit board P1 by soldering.

The socket connector 2 is assembled in the following manner. First, the holding target portion 63 of the socket signal terminal 60 is press-fitted in the narrow holding groove 81A-1 of the socket housing 80 in the front-rear direction, and in this manner, the socket signal terminal 60 is attached to the socket housing 80. At this time, the signal contact arm portion 62 of the socket signal terminal 60 is housed in the narrow housing groove 81A, and the holding target portion 63 is supported by the groove bottom portion of the narrow housing groove 81A. At the same time, the transition portion 65 of the socket signal terminal 60 is housed in the narrow restriction groove 82A.

The holding target portion 73 of the socket power terminal 70 is press-fitted in the wide holding groove 81C-1 of the socket housing 80 in the front-rear direction, and in this manner, the socket power terminal 70 is attached to the socket housing 80. At this time, the power contact arm portion 72 of the socket power terminal 70 is housed in the wide housing groove 81C, and the holding target portion 73 is supported by the groove bottom portion of the wide housing groove 81C. At the same time, the transition portion 75 of the socket power terminal 70 is housed in the wide restriction groove 82B. Either a step of attaching the socket signal terminals 60 or a step of attaching the socket power terminals 70 may be performed first, or these steps may be performed simultaneously.

Next, the holding target plate portion 91 of the socket metal fixture 90 is press-fitted in the metal fixture holding groove 83A of the socket housing 80 from the X2-side, and in this manner, the socket metal fixture 90 is attached to the socket housing 80. Note that a step of attaching the socket metal fixtures 90 may be performed before or at the same time as a step of attaching the socket terminals 60, 70 to the socket housing 80. The socket terminals 60, 70 and the socket metal fixtures 90 are attached to the socket housing 80, and in this manner, the assembly of the socket connector 2 is completed.

Of the socket signal terminal 60 and socket power terminal 70 of the socket connector 2, the signal contact arm portion 62 and the power contact arm portion 72 extend along the front-rear direction (Y-axis direction), and the leg 64 and the leg 74 extend along the coupling direction (X-axis direction). Thus, in a case where plural types of socket connectors with different dimensions in the coupling direction are designed, the length of the leg in the coupling direction is only required to be changed, and it is not necessary to change the length of the contact portion. In a case where the socket housing is designed, a portion of the socket housing corresponding to the leg in the coupling direction is only required to be increased or decreased according to the length of the leg. Thus, according to the configuration of the present embodiment, while a basic configuration of the socket connector is made common, the plural types of socket connectors with the different dimensions in the coupling direction can be easily designed. Moreover, the leg of the present embodiment is in a simple shape extending along the coupling direction, and therefore, the design can be easily made by increasing or decreasing the length of the leg in the coupling direction as compared to, for example, a case where the leg is bent in a complicated shape.

In the socket connector 2, the entirety of the leg 64 of the socket signal terminal 60 and the entirety of the leg 74 of the socket power terminal 70 are exposed through the socket housing 80. The leg 64 and the leg 74 extend in the coupling direction (X-axis direction) along the outer surface of the side wall 82. In the present embodiment, the leg 64 of the socket signal terminal 60 is formed larger in the terminal arrangement direction than the transition portion 65 and the transition portion 66 continuous to each end portion of the leg 64. That is, an interval between the adjacent legs 64 is smaller than an interval between the transition portions 65 and an interval between the transition portions 66. The adjacent legs 64 are close to each other in this manner, and therefore, an excessive increase in the impedance of the leg 64 can be favorably suppressed. The leg 74 of the socket power terminal 70 is formed larger in the terminal arrangement direction than the transition portion 75 and the transition portion 76 continuous to each end portion of the leg 74. Thus, similarly to the leg 64 of the socket signal terminal 60 described above, an excessive increase in the impedance of the leg 74 can be favorably suppressed.

Next, an operation of connecting the connector mounting bodies (circuit boards) to each other will be described. In the present embodiment, an operation of inserting and connecting the connector mounting body I into between the connector mounting body II and the connector mounting body III among the connector mounting bodies II to V already attached to the case C of the electronic device E will be described. Note that when the operation of connecting the connector mounting bodies is performed, the electronic device E is powered off to reduce short-circuit at the terminal of the connector.

First, as shown in FIG. 1A, the connector mounting bodyIis located corresponding to a portion between the connector mounting body II and the connector mounting body III in the coupling direction (X-axis direction) on the rear side (Y2 side) with respect to the connector mounting bodies II, III. Next, the connector mounting body I is moved forward (Y1 direction), and is inserted between the connector mounting body II and the connector mounting body III.

When insertion of the connector mounting body I is started, the upper and lower end portions of the circuit board P1 of the connector mounting body I enter the rails C1 of the case C from the rear, and move forward while being guided by the groove inner surfaces of the rails C1. As a result of forward insertion of the connector mounting body I as described above, the plug connector 1 disposed on the X1-side mounting surface of the circuit board P1 is fitted in and connected to the socket connector 202 of the connector mounting body II as the mating connector, and the socket connector 2 disposed on the X2-side mounting surface of the circuit board P1 is fitted in and connected to the plug connector 301 of the connector mounting body III as the mating connector, as shown in FIG. 2.

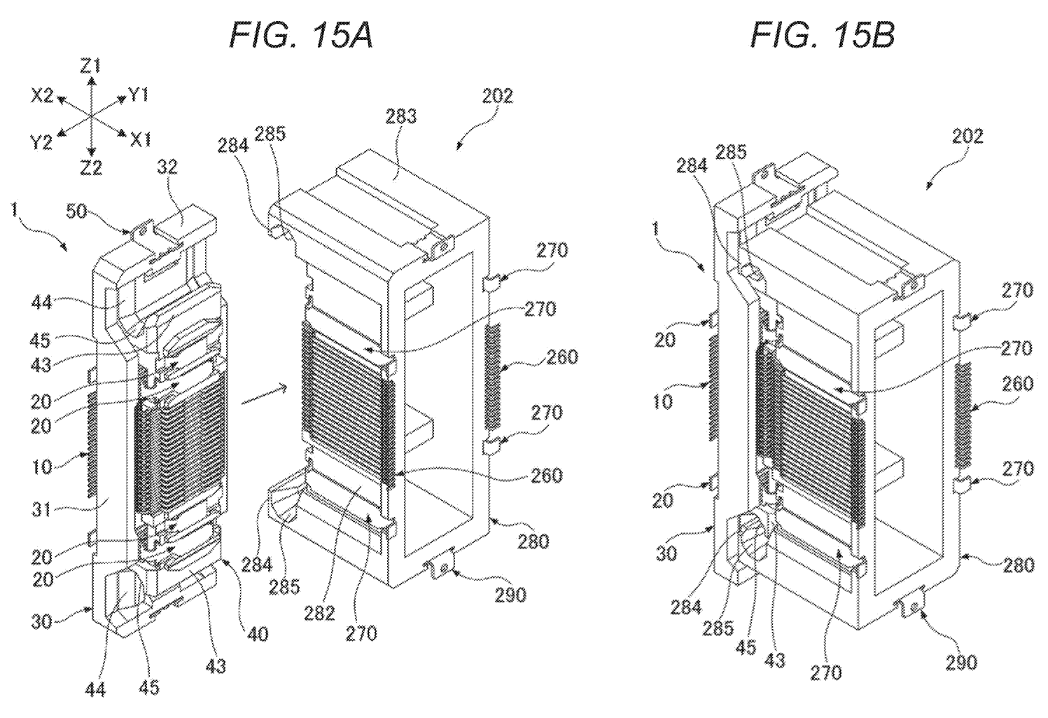

As shown in FIG. 15A, the plug connector 1 is located in rear of the socket connector 202 immediately before an operation of fitting and connecting the plug connector 1 to the socket connector 202 is started. At this time, the guide locking projections 43 of the plug connector 1 are located corresponding to the guide locking grooves 285 of the socket connector 202. When the connector mounting body I is further inserted, the guide locking projection 43 enters the guide locking groove 285, and the guide locking projection 43 and the groove inner surface of the guide locking groove 285 guide each other in the front-rear direction. The plug connector 1 moves forward while being guided by the guide locking projections 43 and the groove inner surfaces of the guide locking grooves 285. At the same time, the guide locking grooves 45 of the plug connector 1 receive the guide locking projections 284 of the socket connector 202 from the front, and the groove inner surfaces of the guide locking grooves 45 and the guide locking projections 284 guide each other in the front-rear direction. The plug connector 1 moves forward while being guided by the groove inner surfaces of the guide locking grooves 45 and the guide locking projections 284. The plug connector 1 and the socket connector 202 guide each other in the front-rear direction, and in this manner, the connectors are smoothly fitted in and connected to each other.

In the course of the fitting connection, the signal contact portion 12B-1 of the plug signal terminal 10 forming the front terminal line (plug signal terminal line) of the plug connector 1 contacts, from the rear, the signal contact 62C of the socket signal terminal 60 forming the rear terminal line (socket signal terminal line) of the socket connector 2. As a result, the signal contact arm portion 62 of the socket signal terminal 60 receives, at the signal contact 62C, pressing force from the signal contact portion 12B-1, and is elastically displaced in the X1 direction. Then, the plug connector 1 further moves forward while the signal contact portion 12B-1 slidably contacts the signal contact 62C.

When the plug connector 1 moves forward, the signal contact portion 12B-1 of the front plug signal terminal line passes by the position of the signal contact 62C of the rear socket signal terminal line, and thereafter, contacts, from the rear, the signal contact 62C of the socket signal terminal 60 forming the front socket signal terminal line. As a result, the signal contact arm portion 62 of the front socket signal terminal 60 receives pressing force from the front signal contact portion 12B-1 at the signal contact 62C, and is elastically displaced in the X1 direction. At this time, the signal contact arm portion 62 is elastically displaced by such a displacement amount that the signal contact arm portion 62 does not contact the stopper 81B.

Substantially at the same time as contact of the front signal contact portion 12B-1 with the front signal contact 62C, the signal contact portion 12B-1 of the plug signal terminal 10 forming the rear plug signal terminal line contacts, from the rear, the signal contact 62C of the socket signal terminal 60 forming the rear socket signal terminal line of the socket connector 2. As a result, the signal contact arm portion 62 of the front socket signal terminal 60 receives, at the signal contact 62C, pressing force from the front signal contact portion 12B-1, and is elastically displaced in the X1 direction. At this time, the signal contact arm portion 62 is elastically displaced by such a displacement amount that the signal contact arm portion 62 does not contact the stopper 81B.

The plug connector 1 further moves forward while the front signal contact portion 12B-1 slidably contacts the front signal contact 62C and the rear signal contact portion 12B-1 slidably contacts the rear signal contact 62C.

In the present embodiment, a distance between the front signal contact 62C and the rear signal contact 62C in the front-rear direction is set greater than the length (dimension in the front-rear direction) of the signal contact portion 12B-1. Thus, in the course of the connector fitting connection, the signal contact portion 12B-1 does not simultaneously contact the front signal contact 62C and the rear signal contact 62C. Consequently, even if the electronic device E is powered on, the short-circuit can be reduced.

In the course of the fitting connection, the power contact portion 22B of the plug power terminal 20 of the plug connector 1 contacts the power contact 72B of the socket power terminal 70 from the rear. As a result, the power contact arm portion 72 of the socket power terminal 70 receives, at the power contact 72B, pressing force from the power contact portion 22B, and is elastically displaced in the X1 direction. Then, the plug connector 1 further moves forward while the power contact portion 22B slidably contacts the power contact 72B.

In the present embodiment, in the plug connector 1, the plug power terminals 20 are provided at different positions in the terminal arrangement direction. In the socket connector 202, the socket power terminals 270 are provided at different positions in the terminal arrangement direction. Thus, the plug power terminal 20 does not contact the socket power terminal 270 which does not correspond to such a plug power terminal 20, and therefore, even if the electronic device E is powered on in the course of the fitting connection, the short-circuit can be reduced.

The plug connector 1 moves forward and the upper and lower end portions of the circuit board P1 contact, from the rear, the front end surfaces closing the front ends of the rails C1, and in this manner, the plug connector 1 reaches a normal fitting position. In this manner, the connector fitting connection operation of the plug connector 1 and the socket connector 202 is completed. By the fitting connection of the plug connector 1 and the socket connector 202, the circuit board P1 of the connector mounting body I and the circuit board P2 of the connector mounting body II are coupled in the coupling direction (X-axis direction).

In a state of the connector fitting connection operation being completed, the elastic displacement state of the signal contact arm portion 62 of the front socket signal terminal 60 is maintained while the signal contact portion 12B-1 of the front plug signal terminal 10 contacts, with contact pressure, the signal contact 62C of the front socket signal terminal 60, as shown in FIG. 16. Moreover, the elastic displacement state of the signal contact arm portion 62 of the rear socket signal terminal 60 is maintained while the signal contact portion 12B-1 of the rear plug signal terminal 10 contacts, with contact pressure, the signal contact 62C of the rear socket signal terminal 60. As a result, in each of the front and rear terminal lines, the plug signal terminal 10 and the socket signal terminal 60 are brought into electric conduction with each other.

Moreover, in the state of the connector fitting connection operation being completed, the elastic displacement state of the power contact arm portion 72 of the socket power terminal 70 is maintained while the power contact portion 22B of the plug power terminal 20 contacts, with contact pressure, the power contact 72B of the socket power terminal 70, as shown in FIG. 17. As a result, the plug power terminal 20 and the socket power terminal 70 are brought into electric conduction with each other.

Further, in the state of the connector fitting connection operation being completed, the plug connector 1 and the socket connector 202 are in a lock state in which the guide locking projection 43 and the guide locking projection 284 are locked to each other in the coupling direction (X-axis direction), as shown in FIG. 18. Thus, a stable connector fitting connection state of the plug connector 1 and the socket connector 2 can be favorably maintained. The front-rear direction (Y-axis direction) which is the direction of inserting and removing the connectors is the direction perpendicular to the coupling direction (X-axis direction), that is, the direction (lock direction) of locking the connectors. That is, the guide locking projection 43 of the plug connector 1 and the guide locking projection 284 of the socket connector 202 are configured not to interfere with the connector fitting connection operation.

Immediately before the start of the connector fitting connection operation, even in a case where the relative positions of the plug connector 1 and the socket connector 202 are shifted from the normal positions in the direction perpendicular to the insertion-removal direction, the elastic portions 15, 25 of the plug terminals 10, 20 of the plug connector 1 are elastically displaced and the movable housing 40 is displaced, and therefore, the shift of the connectors can be absorbed in the course of the connector fitting connection and in the connector fitting state. The movable housing 40 is preferably configured to be displaceable at least in the direction perpendicular to the insertion-removal direction. The plug terminals 10, 20 are configured to allow movement of the movable housing 40 relative to the fixed housing 30 by elastic displacement of the elastic portions 15, 25 of the plug terminals 10, 20.

The socket connector 2 mounted on the X2-side mounting surface of the circuit board P1 of the connector mounting body I is fitted in and connected to, from the rear, the plug connector 301 mounted on the X1-side mounting surface of the circuit board P3 of the connector mounting body III at the same time as fitting connection of the plug connector 1 of the connector mounting body I to the socket connector 202. The socket connector 2 being fitted in and connected to the plug connector 301 from the rear relatively indicates the plug connector 301 being fitted in and connected to the socket connector 2 from the front. The fitting connection operation of the plug connector 301 to the socket connector 2 is substantially similar to the above-described fitting connection operation of the plug connector 1 to the socket connector 202, except for a direction of fitting the plug connector 301. Thus, the description thereof will be omitted. By the fitting connection of the socket connector 2 and the plug connector 301, the circuit board P1 of the connector mounting body I and the circuit board P3 of the connector mounting body III are coupled in the coupling direction (X-axis direction).

In the present embodiment, the circuit boards P1 to P5 are disposed such that each plate surface (principal surface) of the circuit boards P1 to P5 is in the posture perpendicular to the coupling direction (X-axis direction). Assuming that one plate surface of each of the circuit boards P1 to P5 is a first principal surface and the other plate surface opposite to the first principal surface is a second principal surface, the circuit boards P1 to P5 are disposed such that the first and second principal surfaces thereof are perpendicular to the coupling direction of the circuit boards P1 to P5.

The plug connector 1 and the socket connector 202 facing each other in the coupling direction (X-axis direction) are fitted in and connected to each other with one direction (Y-axis direction) parallel with the first and second principal surfaces as the insertion-removal direction. By such connector fitting connection, the circuit board P1 of the connector mounting body I and the circuit board P2 of the connector mounting body II are coupled and electrically connected in the coupling direction (X-axis direction). Moreover, the socket connector 2 and the plug connector 301 facing each other in the coupling direction (X-axis direction) are fitted in and connected to each other with one direction (Y-axis direction) parallel with the first and second principal surfaces as the insertion-removal direction. By such connector fitting connection, the circuit board P1 of the connector mounting body I and the circuit board P3 of the connector mounting body III are coupled and electrically connected in the coupling direction (X-axis direction).

Each plug connector of the circuit boards P1 to P5 has the first guide locking portion, and each socket connector has the second guide locking portion. In the course of fitting and connecting the plug connector 1 and the socket connector 202 (the course of the connector fitting connection), the first guide locking portion (guide locking projection 43 and guide locking groove 45) of the plug connector 1 of the circuit board P1 and the second guide locking portion (guide locking projection 284 and guide locking groove 285) of the socket connector 202 of the circuit board P2 guide each other in the insertion-removal direction. In a state of the plug connector 1 and the socket connector 202 being fitted in and connected to each other (connector fitting connection state), the guide locking projection 43 and the guide locking groove 285 are locked to each other in the coupling direction, and the guide locking projection 284 and the guide locking groove 45 are locked to each other in the coupling direction.

The guide locking projection 43 and the guide locking projection 284 protrude in the direction perpendicular to the coupling direction and the insertion-removal direction, and extend in the insertion-removal direction. The guide locking groove 45 extends in the insertion-removal direction, and in the course of the connector fitting connection, receives and guides the guide locking projection 284. The guide locking groove 285 extends in the insertion-removal direction, and in the course of the connector fitting connection, receives and guides the guide locking projection 43.

In the present embodiment, the adjacent circuit boards are connected via the connectors provided on the mounting surfaces (first and second principal surfaces), that is, the plug connector and the socket connector. Thus, a main board for connecting a plurality of circuit boards and a connector mounted on the main board as in the related art are not necessary, and an increase in the number of components can be suppressed.

In the present embodiment, the plug housing of the plug connector has the fixed housing and the movable housing, and the movable housing is displaceable by elastic displacement of the plug terminal. However, the present disclosure is not limited thereto. The plug housing does not necessarily have the fixed housing and the movable housing. For example, as a modification, the plug housing may be formed as one housing, and may be displaceable by elastic displacement of the terminal. In this case, the terminal may be provided with the elastically-displaceable elastic portion. For example, the terminal may have the elastically-displaceable elastic portion between the connection portion to be connected to the circuit board and the holding target portion to be held by the housing.

In the present embodiment, in only the plug connector of the plug connector and the socket connector, the housing is displaceable, but the present disclosure is not limited thereto. As a modification, in both the plug connector and the socket connector or only the socket connector, the housing may be displaceable. That is, at least one of the housing of the plug connector or the housing of the socket connector is only required to be displaceable.

In a case where the socket housing of the socket connector is displaceable, the socket housing may include a fixed housing and a movable housing and the movable housing may be displaceable by elastic displacement of the terminal, as in the plug housing of the above-described embodiment. Similarly to the above-described modification of the plug connector, the socket housing may be formed as one housing, and the socket housing may be displaced by elastic displacement of the terminal.

In the present embodiment, in the plug connector and the socket connector, the signal terminals of the two terminal lines are disposed at the same positions in the terminal arrangement direction, but the present disclosure is not limited thereto. For example, in a case where a demand for reducing the size of the connector in the terminal arrangement direction is not so high, at least some of the plurality of signal terminals of the two terminal lines may be disposed at different positions in the terminal arrangement direction, as a modification.

In the present embodiment, in the plug connector and the socket connector, the signal terminals are disposed in the two terminal lines, but the number of terminal lines in the present disclosure is not limited thereto. The number of terminal lines may be one or three or more, for example.

In the present embodiment, in the plug connector and the socket connector, the power terminals are disposed at the different positions in the terminal arrangement direction, but the present disclosure is not limited thereto. In a case where a configuration capable of reducing the short-circuit in the course of the connector fitting is employed, the power terminals may be disposed in a plurality of terminal lines, and the power terminals of these terminal lines may be disposed at the same positions, as a modification. As the configuration for reducing the short-circuit, the contacts of the power terminals of the adjacent terminal lines are provided at positions apart from each other in the front-rear direction in the socket connector, and the length of the contact portion of the power terminal in the front-rear direction in the plug connector may be smaller than a distance between the above-described contacts, for example.

In the present embodiment, in the socket connector, the leg of the socket terminal is entirely exposed through the socket housing, but the present disclosure is not limited thereto. Only part of the leg of the socket terminal may be exposed through the socket housing.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A circuit board coupling structure for coupling a plurality of circuit boards,
each of the plurality of circuit boards having a first principal surface and a second principal surface opposite to the first principal surface, and the plurality of circuit boards being disposed such that the first and second principal surfaces are perpendicular to a coupling direction of the plurality of circuit boards,
a first connector being mounted on the first principal surface, a second connector being mounted on the second principal surface, and each of the first connector and the second connector having a plurality of terminals and a housing holding the plurality of terminals,
the first connector and the second connector being fitted in and connected to each other with one direction parallel with the first and second principal surfaces as an insertion-removal direction,
adjacent ones of the circuit boards being electrically connected in such a manner that the first and second connectors facing each other in the coupling direction are fitted in and connected to each other,
the housing of the first connector having a first guide locking portion, and the housing of the second connector having a second guide locking portion, and
the first and second guide locking portions being configured to guide each other in the insertion-removal direction in a course of fitting and connecting the first and second connectors and be locked to each other in the coupling direction in a state of the first and second connectors being fitted in and connected to each other.

2. The circuit board coupling structure according to claim 1, wherein
one of the first guide locking portion or the second guide locking portion has a projection, the other one has a groove, the projection protrudes in a direction perpendicular to the coupling direction and the insertion-removal direction and extends in the insertion-removal direction, and the groove extends in the insertion-removal direction, and in the course of fitting and connecting the first and second connectors, receives and guides the projection.

3. A circuit board coupling structure for coupling a plurality of circuit boards,
each of the plurality of circuit boards having a first principal surface and a second principal surface opposite to the first principal surface, and the plurality of circuit boards being disposed such that the first and second principal surfaces are perpendicular to a coupling direction of the plurality of circuit boards,
a first connector being mounted on the first principal surface, a second connector being mounted on the second principal surface, and each of the first and second connectors having a plurality of terminals and a housing holding the plurality of terminals,
the first and second connectors being fitted in and connected to each other with one direction parallel with the first and second principal surfaces as an insertion-removal direction,
adjacent ones of the circuit boards being electrically connected in such a manner that the first and second connectors facing each other in the coupling direction are fitted in and connected to each other, and
at least any one of the housing of the first connector or the housing of the second connector is displaceable in a direction perpendicular to the insertion-removal direction.

4. The circuit board coupling structure according to claim 3, wherein
at least any one of the housing of the first connector or the housing of the second connector has a fixed housing fixed to the circuit boards via the plurality of terminals, and a movable housing movable relative to the fixed housing, and
the plurality of terminals is bridged between the fixed housing and the movable housing, and is configured to allow movement of the movable housing relative to the fixed housing by elastic displacement of the plurality of terminals.
